(19) United States
(12) Patent Application Publication
(10) Pub. No.: US 2026/0267097 A1
(43) Pub. Date: Sep. 10, 2026

(54) SYSTEM AND METHOD FOR AN OPTICAL INTERCONNECT NETWORK USING MULTI-LAYER WAVEGUIDE STRUCTURES

(71) Applicant: Density AI, Inc., Mountain View, CA (US)

(72) Inventors: Nachiket Raravikar, Mountain View, CA (US); Bill Chang, Mountain View, CA (US); Ganesh Venkat, Mountain View, CA (US); Ron Rosenberg, Mountain View, CA (US); Chang Liu, Mountain View, CA (US); Sameet Ramakrishnan, Mountain View, CA (US); Diwakar Tundlam, Mountain View, CA (US); Elad Alon, Mountain View, CA (US)

(21) Appl. No.: 19/544,633

(22) Filed: Feb. 19, 2026

Related U.S. Application Data
(60) Provisional application No. 63/767,217, filed on Mar. 5, 2025.
(60) Provisional application No. 63/767,157, filed on Mar. 5, 2025.
(60) Provisional application No. 63/796,165, filed on Apr. 28, 2025.
(60) Provisional application No. 63/803,277, filed on May 9, 2025.
(60) Provisional application No. 63/912,168, filed on Nov. 5, 2025.

(51) Int. Cl. G02B 6/43; G02B 6/42; H10B 80/00; H10D 80/30; H10W 70/05; H10W 70/60; H10W 90/00; H10W 90/10

(52) U.S. Cl. CPC G02B 6/43; G02B 6/4214; H10W 70/095; H10W 70/618; H10W 90/10; H10W 90/794; H10B 80/00; H10D 80/30

(57) ABSTRACT

Provided is a multi-layer waveguide structure including a substrate including a wafer-scale or panel-scale interposer, a plurality of stacked optical waveguide layers disposed within or on the substrate, each waveguide layer configured to route optical signals along a predefined optical pathway, an electrical routing layer adjacent to the plurality of stacked optical waveguide layers, a plurality of optical-electrical chiplets bonded to the substrate, and an optical detector, a plurality of optical couplers configured to optically couple the optical emitters and detectors to the stacked optical waveguide layers, and a bonding surface configured to electrically or optically connect one or more compute or memory dies to the interconnect structure.

### CROSS-REFERENCE TO RELATED APPLICATIONS

This patent claims the benefit of U.S. Provisional Patent Application 63/767,217, filed Mar. 5, 2025, titled ALL-TO-ALL DIE-TO-DIE OPTICAL INTERCONNECT NETWORK USING MULTI-LAYER WAVEGUIDE STRUCTURES, U.S. Provisional Patent Application 63/796,165, filed Apr. 28, 2025, titled DIE-TO-DIE PHOTONIC NETWORK FOR WAFER-LEVEL SYSTEM ARCHITECTURES, U.S. Provisional Patent Application 63/767,157, filed Mar. 5, 2025, titled WAFER-SCALE HIGH-RADIX SWITCHING ARCHITECTURE, U.S. Provisional Patent Application 63/803,277, filed May 9, 2025, titled ANY-TO-ANY HIGH-RADIX SWITCH ARCHITECTURES BASED ON OPTO-ELECTRICAL INTERCONNECTS, and U.S. Provisional Patent Application 63/912,168, filed Nov. 5, 2025, titled LATERALLY COUPLED ULED (OR VCSELS)—PHOTO DETECTORS—WITH MULTI-LAYER WAVEGUIDES BACKGROUND. The entire content of each afore-listed earlier-filed application is hereby incorporated by reference for all purposes.

### BACKGROUND

### 1. Field

The present disclosure relates generally to interconnect architectures for die-to-die communication in wafer-scale, panel-scale, and substrate-scale environments.

### 2. Description of the Related Art

As artificial intelligence platforms and high-performance computing workloads continue to expand in scale, the demand for interconnect systems capable of providing extremely high bandwidth with low latency has intensified. These environments frequently require the movement of large data volumes between multiple silicon dies, including processors, memory modules, and specialized accelerators, all of which must operate as part of a tightly coupled system.

Electrical interconnects based on copper conductors encounter increasing challenges in such architectures. Resistive and capacitive effects can limit achievable reach and bandwidth, while equalization and clock recovery circuitry contribute to higher energy consumption. Serializer/deserializer (SerDes) processing further increases latency and complexity, making purely electrical approaches less efficient for wide-parallel, die-to-die communication at scale.

Additionally, the choice of network topologies used for electrical interconnects are limited by the length of electrical traces and multi-hop routing paths. Simple topologies such as 2d-mesh and torus may be chosen whereas other topologies such as folded-Clos, etc., are eschewed due to these constraints. This impacts the efficiency of distributed compute systems and hinders the ability to extend performance linearly as more dies are integrated into a single package or across multiple substrates.

### SUMMARY

The following is a non-exhaustive listing of some aspects of the present techniques. These and other aspects are described in the following disclosure.

Some aspects include a multi-layer waveguide structure, including a substrate comprising a wafer-scale or panel-scale interposer, a plurality of stacked optical waveguide layers disposed within or on the substrate, each waveguide layer configured to route optical signals along a predefined optical pathway, an electrical routing layer disposed adjacent to the plurality of stacked optical waveguide layers, a plurality of optical-electrical chiplets bonded to the substrate, each optical-electrical chiplet including an emitter selected from the group consisting of a micro-light emitting diode, a vertical-cavity surface-emitting laser, a quantum dot light emitting diode, or a silicon photonic modulator, and an optical detector selected from the group consisting of a photodiode or a transimpedance amplifier, a plurality of optical couplers configured to optically couple the optical emitters and detectors to the stacked optical waveguide layers, and a bonding surface configured to electrically or optically connect one or more integrated circuit dies to the interconnect structure.

Some aspects include a tangible, non-transitory, machine-readable medium storing instructions that when executed by a data processing apparatus cause the data processing apparatus to perform operations including bonding a wafer comprising an electrical redistribution layer to a wafer comprising a first photonic layer, the first photonic layer comprising an array of optical emitter structures or photodetector structures configured for optical coupling via grating couplers, tapered transitions, or evanescent couplers, removing at least a portion of a handle substrate of the first photonic layer to expose the first photonic layer for subsequent integration, forming conductive vias through the first photonic layer to electrically connect the first photonic layer to the redistribution layer, the vias having a pitch of 10 μm or less, bonding a second photonic layer comprising an array of optical emitter structures or photodetector structures, and removing at least a portion of a handle substrate of the second photonic layer to expose the second photonic layer, bonding a waveguide-electrical interposer comprising two or more stacked optical waveguide layers configured to provide independent optical routing pathways, forming external connection features comprising hybrid bonding pads or solderable micro-bumps configured for electrical and optical input or output, and attaching at least one compute die, memory die, or power regulation component to the bonding surface of the interposer such that the die overlies at least a portion of the photonic or waveguide layers.

Some aspects include a system, including: one or more processors; and memory storing instructions that when executed by the processors cause the processors to effectuate operations of the above-mentioned process.

### BRIEF DESCRIPTION OF THE DRAWINGS

The above-mentioned aspects and other aspects of the present techniques will be better understood when the present application is read in view of the following figures in which like numbers indicate similar or identical elements:

FIG. 1 illustrates an embodiment of a multi-layer waveguide interposer.

FIG. 2 illustrates an embodiment of a vertically integrated wafer-or panel-level package with optical, electrical, and power delivery layers.

FIG. 3 illustrates an embodiment of a substrate-scale architecture with multiple silicon dies interconnected by optical waveguides.

FIG. 4 illustrates an embodiment of an interconnect architecture with optical-electrical chiplets and switches on a waveguide-electrical interposer.

FIG. 5 illustrates a flow diagram of an embodiment of a method for fabricating a multi-layer waveguide interposer structure.

FIG. 6 illustrates an embodiment of a computing system suitable for implementing aspects of the disclosed techniques.

While the present techniques are susceptible to various modifications and alternative forms, specific embodiments thereof are shown by way of example in the drawings and will herein be described in detail. The drawings may not be to scale. It should be understood, however, that the drawings and detailed description thereto are not intended to limit the present techniques to the particular form disclosed, but to the contrary, the intention is to cover all modifications, equivalents, and alternatives falling within the spirit and scope of the present techniques as defined by the appended claims.

### DETAILED DESCRIPTION OF CERTAIN EMBODIMENTS

To mitigate the problems described herein, the inventors had to both invent solutions and, in some cases just as importantly, recognize problems overlooked (or not yet foreseen) by others in the field of high-density optical and electrical interconnect architectures for wafer-scale and panel-scale computing systems. Indeed, the inventors wish to emphasize the difficulty of recognizing those problems that are nascent and will become much more apparent in the future should trends in industry continue as the inventors expect. Further, because multiple problems are addressed, it should be understood that some embodiments are problem-specific, and not all embodiments address every problem with traditional systems described herein or provide every benefit described herein. That said, improvements that solve various permutations of these problems are described below.

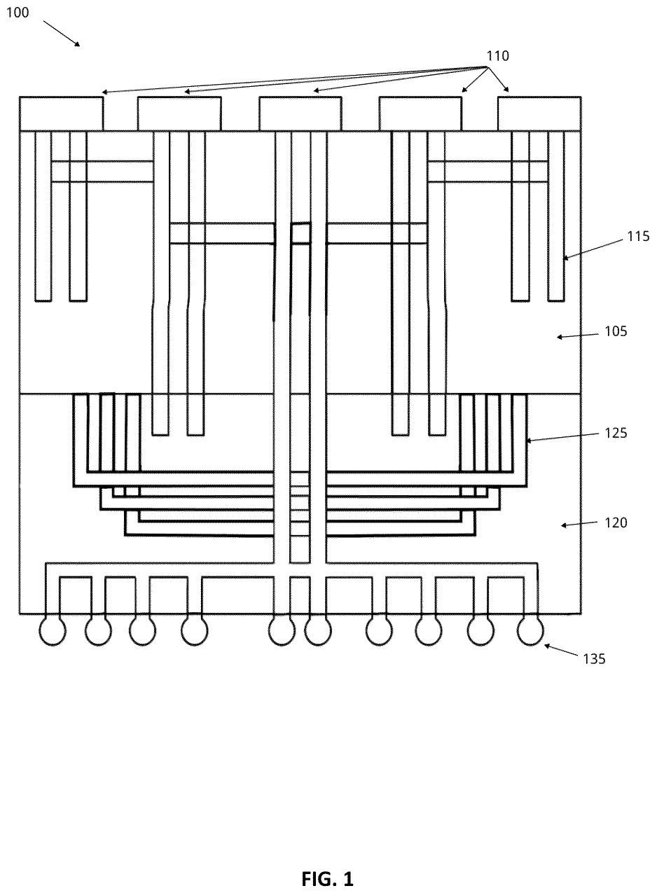

FIG. 1 illustrates, in cross-sectional view, an example of a multi-layer waveguide interposer 100. In some embodiments, interposer 100 may be formed using wafer-to-wafer hybrid bonding techniques and may include a silicon or other semiconductor-based substrate, or an organic substrate with an inorganic bonding layer on a side. A top portion of the structure may include a redistribution layer (RDL) region 105, which may comprise one or more layers of metal interconnects 115 formed on silicon or other dielectric materials. The RDL region 105 may provide routing between compute dies, memory dies, and power regulation components 110.

Disposed above the interposer are a plurality of electrical and compute components 110, which may include processors, high-bandwidth memory (HBM), voltage regulation modules, or other active or passive elements. These components may be electrically and/or optically coupled to the interposer 100 through the RDL region 105. In some embodiments, voltage regulator modules may be located on the side opposite of where the compute and memory dies are positioned. In some embodiments, voltage regulator modules may be positioned on the same side as the compute and memory dies. The lower portion of the structure may include a waveguide-electrical interposer region 120. In some embodiments, the interposer region 120 may comprise a plurality of optical waveguides 125, which may be arranged in stacked layers to provide independent optical routing paths between dies or across substrates. The core materials for waveguides 125 may be fabricated using materials such as silicon nitride (SiN), silicon oxynitride (SiON), aluminum oxide (Al₂O₂), polymer-based dielectric materials, or combinations thereof. Cladding materials may be used to fill gaps around the waveguides 125 and may be fabricated using SiOx or other materials with lower refractive index than the core materials.

In some embodiments, the interposer 100 supports horizontal and lateral optical communication in which modulated optical signals are conveyed predominantly along laterally routed optical waveguides 125. In some embodiments, an emitter of an optical-electrical chiplet may be positioned and oriented so that optical energy couples laterally into a waveguide core, and the waveguide routes the optical signal laterally to a destination region where an optical detector of another optical-electrical chiplet is coupled to receive the optical signal. In some embodiments, lateral coupling may be used for one or more significant routing channels, while other coupling mechanisms are used selectively at specified nodes, layer transitions, or interface locations.

In some embodiments, the optical-electrical chiplets may include arrays of direct driven emitter pixels and detector pixels arranged along an interface edge or sidewall so that coupling occurs through a lateral aperture, lateral evanescent region, or lateral edge-coupling structure. In some embodiments, pixel geometries are selected to promote lateral coupling, including pixel shapes having reflector material on a plurality of sides other than a coupling side facing a waveguide region, and including non-circular or otherwise irregular pixel footprints arranged to direct emitted light toward a laterally adjacent waveguide and to receive light from a laterally adjacent waveguide.

In some embodiments, the horizontal and lateral optical communication provides a parallel lateral interface comprising a plurality of channels that operate concurrently. Multiple laterally coupled channels may be stacked in the vertical direction by bonding multiple photonic layers, with each photonic layer including laterally coupled emitters, waveguides, and detectors, thereby increasing channel count without requiring increased lateral footprint.

In some embodiments, vertical communication is used in combination with horizontal and lateral optical communication. For example, one or more vertical routing structures may couple an optical path from a first photonic layer to a different photonic layer so that an optical signal routed laterally on one layer is transitioned vertically to another layer and then routed laterally on that other layer. In some embodiments, a vertical routing structure optically couples a first layer to a third layer, including configurations in which an optical path is transitioned from a first layer to a third layer while maintaining lateral routing on at least a portion of the path.

In some embodiments, vertical routing structures support routing permutations including split or branching configurations in which an optical signal traveling on a first layer is directed to remain on the first layer and is also directed to a different layer. In some embodiments, vertical routing structures are used selectively to couple between different lateral channels, while a predominant portion of routing for one or more significant channels remains lateral.

The underside of the interposer 100 may include an array of external interconnects 135, which may be implemented as ball grid array (BGA) solder balls, micro-bumps, hybrid bonding pads, or other connection structures. These external interconnects 135 may provide electrical, optical, or power interfaces between interposer 100 and an underlying substrate, board, or system-level packaging structure.

In various embodiments, the interposer 100 may be configured to support energy efficient, high-bandwidth, low-latency communication between a variety of integrated circuit dies while also integrating electrical redistribution, optical routing, and power delivery pathways into a unified substrate.

In some embodiments, optical-electrical chiplets may be embedded fully within build-up layers of interposer 100. In some embodiments, chiplets may be partially recessed into cavities or mounted on a surface of interposer 100. Chiplets may be positioned within die-shadow regions beneath portions of components 110, along perimeter regions, or in dedicated islands distributed across the footprint. The chiplets may include one or more optical emitters (for example uLEDs, VCSELs, quantum-dot emitters, or silicon-photonic modulators), one or more optical detectors (for example PIN or avalanche photodiodes with or without TIAs), and associated driver or receiver circuitry. Placement may be selected to preserve top-side area, shorten electrical paths into RDL region 105, or align with optical features of waveguides 125 in region 120.

In some embodiments, assembly may follow a multi-step bonding sequence in which a wafer including RDL region 105 is bonded to a photonic wafer, a handle substrate is at least partially removed, and fine-pitch conductive vias are formed to connect photonic devices to metal interconnects. In some embodiments, the order of photonic layers may be reversed, multiple photonic layers may be joined before attachment to interposer region 120, or temporary carriers may support intermediate thinning and planarization. Bond interfaces may include oxide-to-oxide, metal-to-metal, polymer-assisted bonding films, or combinations thereof. Substrate removal may include grinding, etching, or chemical-mechanical polishing, and vias may comprise copper, tungsten, or plated stacks with barrier and seed layers selected for reliability at the targeted pitch.

In some embodiments, optical coupling between embedded or surface-mounted chiplets and waveguides 125 may use subwavelength grating couplers, tapered vertical transitions, evanescent coupling regions, or reflective elements (e.g., 45-degree reflective surfaces, facets, or structures) formed within region 120. In some embodiments, coupling may occur through micro-lenses, prism structures, lensed fibers, or free-space elements integrated at a top surface. Ports may be provided at a top surface for fiber egress, at an edge for edge coupling, or at recessed windows aligned to vertical couplers. In some embodiments, emitters may be located external to interposer 100 and coupled through fibers or free-space paths while detectors remain on or within the stack; in some embodiments, both emitters and detectors may be on-interposer.

In some embodiments, the optical coupling between an optical-electrical chiplet and a waveguide 125 may include a lateral coupling interface, such as an edge-coupling region, a lateral evanescent coupling region, a lateral aperture aligned to an emitter or detector edge, or a laterally oriented mode transformer. In some embodiments, a plurality of emitters and detectors may be arranged along one or more lateral coupling edges so that coupling occurs predominantly in a horizontal direction relative to a surface of the interposer 100, with vertical coupling structures reserved for selected inter-layer transitions, crossing relief, or other routing permutations.

In some embodiments, alignment may use embedded fiducials, optical alignment marks, or electrical probe-based correlation to register coupling structures in region 120 to chiplet apertures. Keep-out regions, low-index trenches, or metal shielding features may be included adjacent to coupling sites to reduce parasitic absorption, scatter, or electrical noise. Optical access paths may include through-die apertures when chiplets are positioned beneath portions of components 110.

In some embodiments, optical alignment between an optoelectronic pixel and a corresponding coupling feature may be supplemented with geometric tailoring of the coupling interface to reduce coupling loss. For example, coupling loss at an interface between a microLED pixel or VCSEL pixel and an associated waveguide structure, and/or at an interface between a waveguide structure and a photodiode pixel, may contribute to an overall optical link budget. In such embodiments, one or more coupling structures at an in-coupling interface and/or an out-coupling interface may be configured to reduce coupling loss and increase coupled optical power.

In some embodiments, a coupling waveguide includes an entrance opening (e.g., an aperture to a vertical coupling waveguide) having a size and/or shape selected based on characteristics of a corresponding pixel. The characteristics may include a pixel emission or collection area, a pixel footprint shape, and/or a light source type. For example, a coherent emitter (e.g., a VCSEL) and a non-coherent emitter (e.g., a microLED) may present different optical field distributions at the coupling plane, and the entrance opening geometry may be selected accordingly. In some embodiments, the entrance opening geometry is selected based on a combination of light source type and pixel size and pixel shape, and the selection may be consistent with one or more layout constraints or fabrication constraints.

In some embodiments, one or more design rules may be used to map a given set of pixel characteristics to a corresponding coupling waveguide geometry. For example, one or more design rules may specify an entrance opening size, an entrance opening shape, and/or a taper configuration for a coupling waveguide responsive to the pixel size/shape and source type. Such design rules may be implemented as part of a photonic layout flow and may be applied on a per-pixel basis within an array, including where different pixels within the array have different emission/collection areas and/or different footprint shapes.

In some embodiments, the coupling waveguide geometry may include one or more selectable parameters at or near the pixel interface, including one or more of: an entrance opening size, an entrance opening shape, a taper angle, a taper depth, and/or a waveguide cross-sectional shape. In some embodiments, the entrance opening shape may be substantially square or substantially rectangular, and in other embodiments the entrance opening shape may be non-square and/or non-rectangular (e.g., an elongated shape, a rounded-rectangle shape, or another polygonal or curvilinear shape) to better correspond to a pixel footprint or an optical field distribution at the coupling plane.

In some embodiments, the entrance opening size is selected relative to the pixel emission/collection area. For example, the entrance opening may be larger than the pixel footprint, approximately similar to the pixel footprint, or smaller than the pixel footprint. In some embodiments, the selection of a larger, similar, or smaller entrance opening is coordinated with the taper configuration such that optical energy is guided into an intended waveguide core region while reducing loss associated with overfill, underfill, and/or mode mismatch.

In some embodiments, the coupling interface includes one or more intermediate layers between a pixel and a waveguide opening. For example, a lens structure may be disposed between a pixel and the entrance opening to shape a beam profile and/or to adjust an effective numerical aperture presented to the waveguide. In some embodiments, a bonding stack is present in the coupling region, including one or more dielectric bonding layers, such that the coupling interface is not limited to direct contact between a pixel surface and a waveguide opening. In such embodiments, one or more of the entrance opening size, entrance opening shape, and taper configuration may be selected with consideration of the intermediate layer or layers.

In some embodiments, the above coupling-interface geometry selection is applied across multiple pixel types within a photonic system, including microLED pixels, VCSEL pixels, and photodiode pixels. In some embodiments, an array includes multiple pixels having different sizes and/or shapes, and the corresponding coupling waveguide openings may likewise vary in size and/or shape across the array, such that the coupling interface is tailored on a per-pixel basis rather than using a single entrance opening geometry for all pixels.

In some embodiments, thermal and reliability features may include thermal vias proximate to chiplets, heat spreaders above components 110, and gap-fill dielectrics selected for coefficient-of-thermal-expansion compatibility with surrounding layers. Underfill or mold compound chemistries, stress-relief slots, or localized stiffeners may be incorporated to manage mechanical compliance. Test and calibration features may include electrical probe pads connected to embedded chiplets, optical monitor taps within waveguides 125, on-interposer loopback paths, and control circuitry to adjust emitter bias or receiver thresholds during bring-up and in operation.

In some embodiments, the interposer 100 may include dedicated power and signal corridors routed through and around embedded O/E chiplets to support high-speed, low-latency operation. Through-electrical routing spaces may be formed within or adjacent to emitter epitaxial stacks and detector active stacks to provide vertical connections to the RDL region 105, and apertures or keep-out regions may be included in photonic layers and waveguides 125 to accommodate power and signal input/output structures. These features may be positioned near a mechanical neutral plane to balance thermo-mechanical stresses. In some embodiments, the features may be distributed across the substrate, placed along peripheries, or patterned in symmetric arrays to address structural and thermal constraints.

In some embodiments, embedding photonic chiplets within the interposer 100 may preserve top-side and bottom-side area for components 110 such as compute, memory, and power regulation devices, which may support wafer-scale and panel-scale integration by shortening optical paths and maintaining short electrical reaches into metal interconnects 115. In some embodiments, stacked photonic interposers, co-packaged optics at an edge or top surface, or heterogeneous chiplet packaging may be used to meet layout, yield, or thermal objectives. Sources may be on-interposer or external and coupled by fibers or free-space elements; detectors may be on-interposer, within the stack, or located on companion chiplets. In some embodiments, the silicon chips containing driver and receiver circuits may be hybrid bonded to emitters and photodetectors. In some embodiments, hybrid bonding may facilitate dense, short electrical paths from driver and receiver circuit channels to their respective emitters and photodetectors. In some embodiments, electrical signal “multiplexing and de-multiplexing” may be carried out on the opposite side of the driver and receiver dies. In some embodiments, the driver and receiving circuit dies may contain a through-silicon via. In some embodiments, the driver and/or receiver circuits may be integrated directly into compute and/or memory base dies. Dense and short electrical interconnects may be used to create a connection from compute or memory base dies to direct drive the emitters and photodetectors. In some embodiments, the electrical interconnects may be achieved by having fine line space structures in RDL below compute and memory dies. In some embodiments, the electrical interconnects may be achieved by creating fine electrical structures onto the electrical interposer using an oxide dielectric based copper damascene-like process. The RDL or copper damascene build up layers may be created on the electrical interposer, which may be configured to have pre-bonded emitter and photodetectors. Compute and memory die containing driver and receiver circuits may be bonded to the RDL or copper damascene layers through chip-on-wafer hybrid bonding (in case of copper damascene) or thermocompression bonding (in case of polyimide based RDL), or via wafer to wafer hybrid bonding to a reconstituted wafer constating of compute and memory die to a damascene build up layers onto the O/E interposer.

In some embodiments, an emitter for a single optical channel may be implemented as a cluster of multiple micro-emitters wired in parallel (for example, p-contacts joined together and n-contacts joined together) so that the cluster functions as one optical source. Individual pixels in the cluster may have lateral dimensions less than 10 μm, less than 5 μm, less than 2 μm, or less than 1 μm, and may be arranged in one-or two-dimensional arrays aligned to a common coupling structure (for example, a grating, tapered vertical coupler, or micro-lens). This shorted multi-pixel configuration may reduce effective capacitance per pixel region, support higher modulation bandwidth, and provide aggregate optical power suitable for high-rate signaling.

In some embodiments, an optical transmitter for a single channel may include a cluster of micro-emitters electrically connected in parallel so that the cluster operates as one logical source. Individual pixels in the cluster may have lateral dimensions less than about ten micrometers, and the cluster may be aligned to a shared coupling element that collects emission from the pixel footprint and couples into a guided mode. The cluster may reduce effective capacitance per pixel region and support higher modulation bandwidth while providing aggregate optical power compatible with the intended reach. In some embodiments, the number of active pixels in a cluster may be adjusted dynamically to meet channel power targets, and segmented clusters may be driven with independent phase or amplitude profiles to shape the emission toward the coupling region. Thermal and electrical layout around the cluster may include local shields, low-index trenches, and thermal vias to manage parasitics and temperature rise.

In some embodiments, smaller pixel sizes may support faster carrier dynamics and reduced junction capacitance, which may benefit optical modulation bandwidth and transition times. Pixel scaling may be balanced against drive current and thermal considerations, and channel power may be managed by selecting the number of active pixels in a cluster, by duty-cycle or bias control, or by current-steering drivers with optional pre-emphasis. In some embodiments, segmented pixel clusters may be driven independently to allow adaptive power scaling, dynamic beam shaping toward the coupling region, or multi-level amplitude modulation.

In some embodiments, wide-parallel electrical input-output signaling may originate at a compute die beachfront, with many lanes operated at modest per-lane data rates and short electrical reach, in contrast to high-rate serial links. In some embodiments, a serial interface may present on the order of ~10 lanes at ~200 Gb/s each for an aggregate beachfront bandwidth of ~2 Tb/s over reaches on the order of ~1 meter, with electrical energy per bit that may be on the order of ~5-10 pJ/bit. By comparison, a wide-parallel electrical interface may achieve a similar aggregate bandwidth (~2 Tb/s) using ~200 lanes at ~10 Gb/s each over short reaches on the order of a few millimeters (e.g., ~2 mm), with electrical energy per bit that may be less than about 1 pJ/bit, depending on routing, impedance environment, and driver design.

In some embodiments, the disclosed optical layer may extend the effective reach of such wide-parallel beachfront interfaces while maintaining low energy per bit, by mapping each electrical lane to one or more optical pixels within an optical-electrical chiplet. As a non-limiting example, one optical pixel operated at ~10 Gb/s may correspond to one ~10 Gb/s electrical lane. In another non-limiting example, ten optical pixels operated at ~1 Gb/s each may collectively correspond to a ~10 Gb/s electrical lane. In some embodiments, an emitter-side driver may receive a ~10 Gb/s electrical input and apply integer multiplexing (e.g., M=10) to generate ten ~1 Gb/s electrical outputs, each driving a respective micro-emitter pixel (e.g., a micro-LED pixel). The ten pixels may couple into ten respective waveguides through subwavelength grating, tapered-vertical, or evanescent couplers. At a receiving node, ten photodiode pixels may each receive a corresponding optical channel and deliver ten ~1 Gb/s electrical outputs to a receiver front end (e.g., a TIA array), which may apply complementary integer de-multiplexing to reconstruct a ~10 Gb/s lane for handoff to logic.

In some embodiments, groups of electrically shorted micro-emitter pixels may be driven by a single de-multiplexed ~1 Gb/s driver output to provide pixel-level redundancy and to shape optical power delivery to a coupling region. Pixel clustering, lane grouping, and multiplexing ratios may be selected based on optical loss budgets, coupling efficiency, and bandwidth targets. Using these mappings, the optical fabric may provide wafer-or panel-scale reach for wide-parallel beachfront interfaces while maintaining energy per bit on the order of less than about 1 pJ/bit, subject to device class, wavelength plan, and materials selections.

In some embodiments, detectors may be implemented as segmented photodiode arrays tied to a common electrical node or to a shared transimpedance amplifier, which may support tuning of effective capacitance and responsivity. Alternative receiver implementations may use avalanche photodiodes with controlled gain, germanium or III-V photodiodes bonded to silicon circuitry, or balanced detection schemes to reduce common-mode noise. Some embodiments may include standard off the shelf silicon photodiode pixels such as commonly used as image sensors.

In some embodiments, optical combination from a multi-pixel emitter cluster into a single waveguide may be facilitated by coupling structures that collect emission over the cluster footprint, including apodized gratings, shallow-etched vertical couplers, 45-degree reflector cavities, or micro-lens features formed in passivation. In some embodiments, each pixel may couple to a distinct sub-aperture within a composite coupler, with the sub-apertures summing into one guided mode or into a set of co-propagating modes that are transformed into a fundamental mode by a mode-filtering section.

In some embodiments, optical coupling between an optoelectronic pixel and a photonic fabric may include a vertical capture portion and a lateral routing portion. For example, optical energy emitted by a microLED pixel or VCSEL pixel may be coupled into a vertical waveguide capture structure and a dedicated intermediate structure may be disposed to redirect at least a portion of the optical energy from a predominantly vertical propagation direction into a predominantly horizontal propagation direction, for coupling into a horizontal waveguide that propagates across the photonic fabric or interposer.

In some embodiments, the intermediate structure comprises a lateral light deviator configured to couple optical energy from the vertical waveguide capture structure into the horizontal waveguide. In some embodiments, the lateral light deviator is configured for use with coherent light and/or non-coherent light, such that the lateral light deviator supports coupling for pixels that emit coherent optical energy and for pixels that emit non-coherent optical energy as well as for mixed arrays that include both types of emitters.

In some embodiments, the lateral light deviator includes a reflective surface configured to redirect optical energy. For example, a mirror structure may be disposed at or near a coupling region between the vertical waveguide capture structure and the horizontal waveguide. In some embodiments, the mirror structure includes a metal film, such as an aluminum film, providing a reflective interface to turn a beam from the vertical capture structure into the horizontal waveguide. In some embodiments, the reflective surface is oriented at an angle relative to the vertical propagation direction, and the angle may be about forty-five degrees, greater than forty-five degrees, or less than 45 degrees. In some embodiments, the reflective surface is substantially planar (e.g., a straight facet), and in other embodiments the reflective surface is curved. Curved reflective surfaces may be used to modify a wavefront shape, reduce divergence, and/or improve coupling into a target mode of the horizontal waveguide.

In some embodiments, the lateral light deviator includes a diffractive structure configured to redirect optical energy from the vertical capture structure into the horizontal waveguide. For example, the lateral light deviator may include a diffraction grating positioned and configured to couple light out of the vertical capture structure and into the horizontal waveguide. In some embodiments, the diffraction grating includes one or more dielectric materials such as AlN, SiN, SiOx, and/or AlOx. In some embodiments, the diffraction grating is configured based on refractive-index contrast between the grating material and a waveguide material (e.g., a waveguide core and/or cladding material), such that the grating redirects optical energy in a controlled manner into a lateral propagation direction.

In some embodiments, the lateral light deviator is not limited to a single category of redirecting structure. For example, a lateral light deviator may be implemented as a reflective mirror structure or as a diffractive grating structure, and alternative implementations may include mirror structures spanning planar and curved geometries and spanning angles that are about forty-five degrees as well as angles higher or lower than forty-five degrees. In some embodiments, different pixels or different channels within a multi-channel photonic fabric may use different lateral light deviator implementations based on one or more of emitter type, wavelength, divergence characteristics, waveguide dimensions, and/or layout constraints.

In some embodiments, electrical and thermal design around embedded chiplets may include local ground shields adjacent to coupling sites, low-index trenches to limit parasitic coupling, thermal vias positioned beneath driver/receiver hot spots, and gap-fill dielectrics selected for coefficient-of-thermal-expansion compatibility. Test features may include electrical probe pads to access embedded devices, optical monitor taps in waveguides 125, and loopback paths to characterize coupling efficiency and eye quality after assembly.

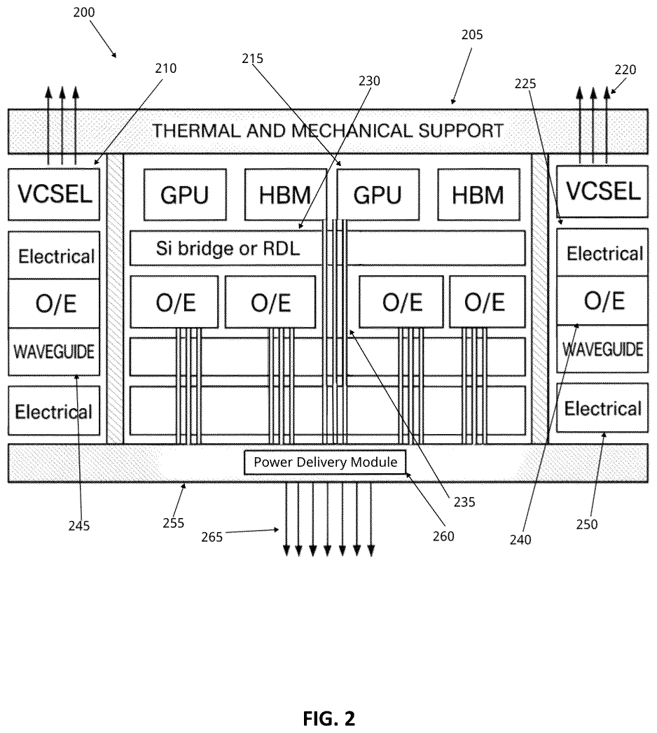

FIG. 2 illustrates, in cross-sectional view, an embodiment of a vertically integrated wafer-level or panel-level package 200 configured to support high-bandwidth optical communication and distributed compute operation. In the depicted example, package 200 includes a multi-layer stack extending from an upper thermal and mechanical support region 205 to a lower thermal and mechanical support region 255. The lower region 255 may further incorporate a power delivery module 260, which may be electrically coupled to one or more external power connections 265.

The upper portion of the structure may include a variety of components 215, such as graphics processing units (GPUs) and high-bandwidth memory (HBM) modules. In some embodiments, optical sources 210 may also be integrated within the upper portion. The optical sources 210 may include, for example, vertical-cavity surface-emitting lasers (VCSELs), micro-light-emitting diodes (uLEDs), quantum dot emitters, silicon photonic modulators, or other suitable devices. The optical sources 210 may be directly coupled into on-package optical waveguides or, in some embodiments, may be optically coupled to external optical fibers 220, which can provide additional routing flexibility for intra-package or inter-package communication. These compute, memory, and optical components may be coupled through redistribution layers and power vias 235 to the underlying power delivery module 260. In some embodiments, HBM may be stacked above GPUs or vice versa (GPU above HBM) via hybrid bonding or flip chip bonding. The whole HBM-GPU stack may be further assembled onto the waveguide electrical interposer. An array of multiple such HBM-GPU ‘stacks’ may be connected to each other via an ‘all to all’ network supported using the abovementioned O/E chiplets and waveguide electrical interposers. O/E chiplets may contain uLEDs or VCSELs and the corresponding photodiodes.

Intermediate layers of package 200 may comprise electrical redistribution and bridging structures, such as a polyimide-copper RDL 225 or a silicon bridge 230 or a silicon interposer configured to provide fine-pitch electrical interconnects between compute and memory components. Beneath the RDL 225 may be a layer of optical-electrical (O/E) chiplets 240, disposed within a dielectric material such as oxide. The O/E chiplets 240 may include optical emitters, detectors, and associated driver or receiver circuitry, and may be electrically coupled through vias to the power delivery module 260.

A waveguide layer 245 may be positioned beneath the O/E chiplets 240, the waveguide layer comprising one or more stacked optical waveguide structures configured to provide optical signal routing between components of the package or between the package and external devices. Additional redistribution or build-up layers 250 may be included beneath the waveguide layer 245, such as a polyimide-copper redistribution layer or a combination of oxide-copper build-up layers with polyimide-copper redistribution layers, thereby providing electrical routing flexibility.

In various embodiments, the seven-layer stack of package 200 may be configured to integrate optical, electrical, thermal, and power delivery pathways within a unified wafer-or panel-scale assembly, supporting scalable high-performance computing architectures.

In some embodiments, the package 200 may be realized within wafer-level or panel-level platforms, or in singulated 2.5D or 3D formats. Off-the-shelf packaging families such as multi-chip modules with embedded interconnect bridge (e.g., Intel's EMIB™ ), die-on-die FOVEROS™ integrations, or chip-on-wafer-on-substrate architectures may be adapted to incorporate the waveguide-electrical stack described herein. In some embodiments, the waveguide-electrical interposer may be hybrid bonded “onto” the inorganic layer on top of an organic substrate and/or to the silicon or ceramic core of an organic substrate. Compute and memory dies may sit on top of the waveguide electrical interposer. The waveguide-electrical interposer may be arranged to provide any-to-any optical communication between dies located within a single package 200 or across multiple packages, with optical layers extending the effective reach and bandwidth density of wide-parallel interfaces across a tray, rack, or cabinet.

In some embodiments, communication links may be provisioned between any two dies, independent of their relative placement in the stack. Optical-electrical chiplets that include micro-LEDs and VCSELs may be selected to support short-reach (e.g., up to 10 meters) and longer-reach (e.g., >10 meters) photonic transmission, respectively. Target performance may include aggregate bandwidth densities on the order of about 10 Tb/s/mm and energy per bit of about 1 pJ/bit or less, subject to device technology, waveguide loss, and thermal design.

In some embodiments, the top mechanical/thermal region 205 may incorporate features for optical fiber attachment and management. Example features may include surface gratings or micro-lens structures aligned to fiber ferrules, alignment fiducials, strain-relief anchors for pigtails, and adhesive keep-out zones compatible with optical materials. Top-side coupling to optical sources 210 located within deeper layers may be supported by vertical couplers or reflective turning elements positioned above the waveguide layer 245.

In some embodiments, a molded dielectric layer positioned beneath the top region 205 may house functional devices, including optical sources 210, compute devices, memory components 215, etc. The molded layer thickness may be about 700-800 μm, with the profile selected to accommodate component heights and planarity requirements.

In some embodiments, an electrical interconnect layer may be implemented as a polyimide-copper RDL 225 or as a silicon bridge 230 or a silicon interposer to provide fine-pitch, low-latency electrical paths between components 215. This layer may have a thickness of 100-200 μm and may include dedicated power and ground planes, test pads for wafer-level probing, and impedance-controlled traces for clock and control signaling. In some embodiments, this layer may have a thickness greater than 200 μm or a thickness less than 100 μm. In some embodiments, electrical build up layers 225 or 230 may be made using copper damascene type process. Copper damascene structures may provide very fine line and space and may not require a separate silicon interposer or a bridge.

In some embodiments, an O/E chiplet layer 240 may embed optical-electrical chiplets within an oxide-based dielectric. The chiplets may include emitters, photodiodes, and associated driver or TIA circuitry, and may further incorporate inductors, capacitors, or power devices to support localized voltage regulation. Placement may be selected to align emitter/detector apertures to coupling features in the waveguide layer 245, while maintaining short electrical paths to the RDL.

In some embodiments, the waveguide routing layer 245 may be configured to couple both to on-chiplet emitters and to external fiber interfaces. In some embodiments, the layer thickness may be 100-200 μm. In some embodiments, the layer thickness may be between approximately 20-100 μm. In some embodiments, the routing layer may include one or more optical planes with vertical transitions, mode transformers, or reflective elements to route signals between components 215 and off-package ports. Material selections for cores and claddings may be chosen to balance propagation loss, bend radius, and thermal stability. In some embodiments, optical layer thickness and vertical coupler thickness may be 20 microns or less. Electrical routing layers may take up much of the remaining thickness.

In some embodiments, a second electrical routing layer 250 may provide additional power distribution and signal breakout. This layer may be realized as a polyimide-copper RDL, a copper-oxide buildup, or ABF (Ajinomoto buildup film)-copper, a combination thereof, with a representative thickness of about 100-200 μm. Stitch-vias may form low-impedance paths to the power delivery module 260.

In some embodiments, the bottom mechanical/thermal region 255 may integrate the power delivery module 260, which may include discrete regulators, inductors, capacitors, and current-sense components distributed across the surface. External power connections 265 may enter through the bottom side and propagate upward through vias and planes to supply the O/E chiplets 240, the waveguide-electrical stack, and the components 215. The topology of power lines and the placement of elements within the power delivery module 260 may be optimized for current density, transient response, and thermal constraints while maintaining mechanical compliance across the vertical stack. In some embodiments, power delivery components such as integrated voltage regulators typically based on silicon may be integrated within any of the buildup layers of the optical electrical interposer.

In some embodiments, a multi-step process flow may be used to fabricate the vertically integrated structure described herein, incorporating photonic, electrical, and mechanical layers into a unified system-on-wafer or system-on-panel package. The following description outlines one possible sequence of fabrication steps; however, it should be understood that alternative process flows, material choices, bonding orders, or integration strategies may be adopted depending on manufacturing constraints, design preferences, or target performance criteria. The described process may be implemented using wafer-level, panel-level, or chip-scale techniques, and may be adapted for either embedded or surface-mounted optical-electrical components. The examples provided herein are intended to illustrate representative methods for forming the proposed stack and are not intended to limit the scope of the disclosure to any particular sequence or technique.

In some embodiments, the fabrication process may begin with the formation of a waveguide-electrical interposer configured to support high-density optical and electrical routing across a wafer-scale or panel-scale package. The interposer may include a multi-layer optical waveguide stack, with at least eight waveguide layers in certain implementations. Based on current estimates, a waveguide pitch of approximately 960 nanometers may support optical coupling to and from approximately 6000 uLEDs and 6000 photodiodes (PDs) within a 1 mm×7.5 mm footprint, facilitating a beachfront bandwidth of approximately 10 Tbps/mm assuming a per-pixel switching rate of 1 gigabit per second. In some implementations, higher pixel modulation speeds may yield proportionally higher bandwidth density.

The top surface of the interposer may include chemical-mechanical polished (CMP) oxide with recessed metal pads that are compatible with hybrid bonding processes, such as chip-on-wafer bonding, to allow the subsequent attachment of O/E chiplets. While the illustrated configuration includes eight waveguide layers, variations may include 2, 4, 8, 16 or more layers, depending on routing requirements, link distances, and wavelength compatibility. In some embodiments, the waveguide layers may support operation at wavelengths between 400 nm and 1000 nm, with insertion losses of less than 10 dB over link distances ranging from approximately 300 mm (in wafer-scale applications) to 500 mm (in panel-scale implementations).

In addition to waveguide routing, the interposer may incorporate electrical vias and power line layers to support vertical power delivery to attached components. Electrical pads may be formed on one or more surfaces of the interposer to allow attachment of power delivery components, such as voltage regulators or passive elements, using mass reflow, thermo-compression bonding, or other techniques. The precise stack-up of waveguide, electrical, and dielectric layers may vary depending on system-level performance targets and integration constraints, and the examples provided herein are not intended to limit the scope of the architecture to a specific interposer geometry or bonding process.

Following the fabrication of the waveguide-electrical interposer, one or more O/E chiplets may be attached to the interposer surface using chip-on-wafer (CoW) hybrid bonding techniques. The O/E chiplets may include integrated uLEDs, PDs, VCSELs, driver circuits, and/or transimpedance amplifiers (TIAs), and may be placed selectively based on the location of corresponding optical waveguides and electrical interconnects within the interposer. After chiplet placement, the interposer surface may be filled with a dielectric oxide material to encapsulate the chiplets and prepare a planarized surface suitable for subsequent wafer-on-wafer (WoW) or chip-on-wafer (CoW) bonding or additional metallization.

In some embodiments, stacked channels are formed by bonding a plurality of photonic layers, each photonic layer including laterally coupled emitter pixels, detector pixels, and associated waveguides. The photonic layers may be bonded in a sequence in which a first photonic layer is bonded and exposed, and one or more additional photonic layers are subsequently bonded to build a multi-layer stack of laterally routed channels. In some embodiments, the stacked photonic layers are bonded to a silicon substrate that includes circuitry associated with drivers, receivers, or other interface circuitry.

In some embodiments, electrical access to emitter pixels and detector pixels is provided by vertical electrical vias routed from a CMOS metal stack to contacts associated with the photonic layers. In some embodiments, at least a subset of electrical routing is formed laterally within a dielectric layer while vertical vias provide access between layers, and in some embodiments lateral routing is reduced by accessing pixels substantially through vertical vias. In some embodiments, electrical access is provided from a backside of a silicon substrate using through-silicon vias (TSVs), including configurations in which photonic layers are stacked on a backside of the silicon substrate and the electrical vias traverse the photonic stack.

The top surface of the resulting stack may be treated to create a hybrid bond-capable interface, comprising chemical-mechanical polished oxide with recessed metal pads for electrical and optical connectivity. This surface may serve as a bonding interface for the attachment of a second wafer, which may contain either additional electrical routing layers or a PI-Cu RDL, depending on the system design. In some embodiments, where wafer bowing or warpage is a concern during bonding, a carrier wafer with temporary adhesive may be applied beneath the electrical layer of the waveguide interposer to provide mechanical support during CoW and WoW bonding processes. The carrier and adhesive materials may be removed at a later stage, once structural stability is achieved. The choice between PI-Cu RDL build-up or full wafer-on-wafer bonding may vary depending on routing density, layer count, and thermal compatibility, and the disclosed process flow is intended to encompass a range of manufacturing options.

In some embodiments, a photonic fabric wafer may be integrated onto an electrical substrate that is based on organic substrate technology, where the photonic fabric wafer includes integrated optical waveguides and optoelectronic devices (e.g., microLEDs or VCSELs and photodiodes).

In some embodiments, the electrical substrate may be implemented as build-up layers of copper and organic dielectrics formed on a substrate “core.” The build-up layers may comprise standard substrate materials, including but not limited to Ajinomoto build-up film (ABF) and/or polyimide (PI). The core material may comprise, by way of example and without limitation, an organic core, a glass core, a glass-cloth core, a laminate core (e.g., copper-clad laminate), and/or a silicon core.

In some embodiments, to facilitate hybrid bonding between the photonic fabric wafer and an organic substrate stack (e.g., ABF or PI build-up), one or more inorganic hybrid-bond-capable layers may be added to a mating surface of the substrate, and corresponding matching layers may be provided on the photonic fabric wafer. Example inorganic bonding layers include silicon oxide and/or silicon nitride, or other hybrid-bond-compatible materials that may be deposited onto organic substrates at relatively low temperatures (e.g., less than 400° C.), thereby respecting thermal budgets associated with organic substrate materials and/or pre-formed circuitry.

In some embodiments, a wafer-on-wafer hybrid bonding process may be used, and the substrate size may be selected to match the photonic fabric wafer size (e.g., up to 300 mm diameter substrates bonded to a photonic fabric wafer). In some embodiments, compute, memory, and/or switch dies may be attached on a photonic fabric side of the resulting assembly, while power delivery solutions may be attached on a bottom side of the substrate (i.e., the side opposite the photonic fabric).

In some embodiments, the photonic fabric wafer may be relatively thin (e.g., less than 400 μm) and may be provided with a carrier wafer as structural support, the carrier wafer being attached to the photonic fabric wafer using a sacrificial adhesive. The carrier wafer and sacrificial adhesive may be removed after the photonic fabric wafer has been attached to the substrate or substrate core (e.g., after wafer-on-wafer hybrid bonding, or after another wafer-level attachment process). Following removal, one or more RDL and/or hybrid-bond-capable layers may be formed on an exposed electrical side of the photonic fabric wafer, and compute and/or memory dies may thereafter be attached (e.g., by hybrid bonding, thermo-compression bonding, and/or reflow).

In some embodiments, the photonic fabric wafer may be integrated by bonding the photonic fabric wafer onto a substrate that includes the core and the organic build-up layers described above. Two representative integration “possibilities” are described. In some embodiments, hybrid-bond layer formation may be performed to prepare one or both mating surfaces, followed by hybrid bonding of the photonic fabric wafer to the substrate. After hybrid bonding, RDL and/or hybrid layers may be formed on a top side of the photonic fabric wafer to facilitate subsequent compute and/or memory attachment.

In some embodiments, rather than hybrid bonding the photonic fabric wafer to the substrate, pads may be formed for thermo-compression bonding or reflow attachment. The photonic fabric wafer may then be attached to the substrate by thermo-compression bonding or reflow, optionally with underfill and/or an exposed photonic fabric mold arrangement. After such attachment, RDL and/or hybrid layers may be formed on a top side of the photonic fabric wafer to facilitate compute and/or memory attachment.

In some embodiments, the photonic fabric wafer may be bonded directly to an organic substrate core via a wafer-on-wafer hybrid bonding process prior to forming substrate build-up layers. In such embodiments, matching inorganic hybrid bonding layers may be formed on both the photonic fabric wafer and the core material, and the sizes of the core and photonic fabric wafer may be selected to match.

After bonding the photonic fabric wafer to the substrate core, build-up layers may be formed. In some embodiments, ABF build-up layers may be grown “below” (i.e., on the opposite side of) the core, while polyimide-based fine-pitch layers may be grown onto the photonic fabric wafer (e.g., on the photonic fabric side intended for compute die attachment). In some embodiments, ABF layers may be grown on both sides of the core. In some embodiments, compute, memory, and/or switch dies may be bonded to the photonic fabric side, while power delivery solutions may be bonded to the ABF or core side.

In some embodiments, a substrate core is provided and a photonic fabric wafer is provided. Hybrid bond layer formation is performed to form a hybrid-bond-capable interface between the photonic fabric wafer and the substrate core. The photonic fabric wafer is then hybrid bonded to the substrate core. Following hybrid bonding, substrate build-up layers are formed, including polyimide layers formed onto the photonic fabric side and ABF layers formed onto the core side. In some embodiments, ABF layers may be formed in different stack-ups relative to the core (including embodiments in which ABF layers are formed on both sides of the core), while maintaining the arrangement in which the photonic fabric side is used for compute and/or memory attachment and the opposite side is used for power delivery attachment.

After preparation of the interposer surface with embedded O/E chiplets and CMP-treated oxide, multiple process flow options may be used to complete the assembly of the compute and memory package. In a first approach, a PI-Cu RDL may be built directly on top of the O/E waveguide-electrical interposer surface, using the exposed metal pads as the starting interface. In this embodiment, compute and memory components such as GPUs and HBM dies may be placed onto the RDL surface, followed by molding and surface polishing steps to encapsulate the components and planarize the structure. This process may simplify alignment between the O/E chiplets and active dies while allowing efficient integration of power, clock, and control distribution networks through the RDL layers.

In some embodiments, a complete functional silicon “package” may be fabricated separately, including one or more silicon or glass substrates, embedded dies, passive components, and metal routing layers. Once this separate package is formed, a topmost inorganic layer, such as an oxide-copper (oxide-Cu) stack, may be deposited to create a bonding interface. This layer may then undergo chemical-mechanical polishing and dishing to form recessed metal bonding pads. The resulting surface may be hybrid WoW bonded onto the previously prepared O/E waveguide-electrical interposer, creating a composite structure that connects compute, memory, and photonic subsystems across multiple functional layers. This second approach may allow greater flexibility in manufacturing and component sourcing and may be advantageous in cases where the compute package is manufactured separately or by a different vendor. In either flow, process variations may be applied depending on system alignment tolerances, bonding compatibility, and thermal or mechanical constraints.

In some embodiments, a complete functional semiconductor package may be fabricated independently, wherein one or more silicon or glass substrates are assembled with embedded dies, memory modules (e.g., HBM), passive components, and associated metal interconnect layers. This stand-alone package may undergo standard back-end-of-line processing, including metallization and encapsulation steps, followed by singulation into individual units. Each singulated unit may then be subjected to electrical and optical test procedures to verify functional performance, thereby identifying a pool of known-good-die (KGD) packages.

Once qualified, these known-good functional silicon may be selectively bonded onto a corresponding O/E waveguide interposer. In this embodiment, the top surface of the singulated package may include a planarized inorganic bonding interface, such as an oxide-copper stack, which may be chemical-mechanical polished and dished to form bonding pads that align with the hybrid bonding interface of the waveguide interposer. This approach may allow for targeted assembly using only fully tested components, improving overall yield and reducing integration risk in wafer-level or panel-level platforms. Additionally, the decoupling of functional silicon fabrication from photonic interposer assembly may provide increased flexibility in supply chain management, manufacturing throughput, and design partitioning, particularly when the photonic interposer and compute layers are produced in separate facilities or by different vendors. Variations in bonding material, die thickness, and alignment schemes may be introduced to accommodate thermal and mechanical tolerances specific to the use case.

In some embodiments, once the full package assembly is complete, whether by direct build-up on the interposer or by bonding of a separately fabricated compute package, mechanical access holes may be formed through the package structure to support the integration of thermal and mechanical clamping hardware. These holes may be drilled or laser-ablated at predefined locations that align with mechanical mounting features in the surrounding system infrastructure, such as cold plates, heat spreaders, or enclosure frames. The insertion of clamping screws or similar fasteners through these openings may assist in maintaining mechanical alignment, managing interfacial pressure, and promoting efficient thermal transfer across the vertical stack.

The clamping mechanism may be particularly beneficial in high-power systems where die-to-die and package-to-package planarity must be preserved during operation or under thermal cycling. In some configurations, the placement and diameter of the access holes may be optimized to balance structural rigidity and thermal conductivity, while maintaining sufficient clearance from functional routing layers and optical channels. This thermal-mechanical anchoring strategy may complement or replace adhesive-based bonding in certain applications and may be adapted based on the cooling method, system form factor, or package thickness. Variations in clamp design, material choice, and fastener type may be incorporated depending on assembly tolerances and target application requirements.

Following completion of the functional silicon and optical layers, the power delivery module (PDM) assembly may be implemented to provide system-level electrical power to the integrated components. In some embodiments, the PDM may be located on the bottom-most layer of the package, occupying a dedicated mechanical and thermal support region within the interposer stack. The PDM may comprise one or more integrated voltage regulators, power field-effect transistors, inductors, capacitors, and associated control circuitry, configured to distribute regulated voltage levels to various layers of the compute system. The module may be bonded to predefined power delivery pads located on the underside of the waveguide-electrical interposer using techniques such as mass reflow, solder compression, or thermo-compression bonding, depending on assembly constraints and current handling requirements.

In some implementations, the PDM may be realized as a single consolidated unit, while in others, the module may be partitioned into multiple discrete components distributed across the surface of the bottom layer. This distributed configuration may be used to improve current distribution, minimize localized heating, and provide redundancy or isolation across power domains. Power interconnects routed through the interposer stack may electrically couple the PDM to integrated circuit dies, memory modules, optical-electrical chiplets, and other peripheral circuitry, with routing paths optimized for minimal resistance, low inductance, and thermal stability. The choice of materials, spatial arrangement, and interconnect topology for the power module assembly may vary depending on the application-specific current density, voltage levels, and power conversion efficiency targets.

In some embodiments, following completion of the photonic, electrical, and mechanical stack, optical fiber pigtail assemblies may be connected to the optical interfaces of the package to establish high-bandwidth links between the system and external components. These pigtails may be coupled to optical transmitters and receivers, such as VCSELs or uLEDs, as well as to input/output ports of the integrated waveguide layer. Optical coupling may occur through top-side, edge-side, or angled interfaces, depending on package geometry, fiber routing constraints, and system-level integration preferences. The fiber pigtails may be aligned to dedicated fiber attach structures or optical vias that interface with either the surface-mounted photonic chiplets or the waveguide terminations embedded within the interposer stack. Coupling strategies may include adhesive alignment, passive ferrule structures, micro-lens integration, or actively aligned fiber connectors, with coupling loss, thermal drift, and mechanical tolerances considered during assembly. In some configurations, the fiber routing may be organized to support top-side vertical escape, allowing optical links to extend perpendicularly from the package for compact module stacking. In other configurations, fibers may exit laterally or diagonally from the edge of the package, depending on system layout and bandwidth density requirements. The specific fiber attachment method and geometry may vary across embodiments and may be tailored for application-specific considerations including connectorization, bend radius constraints, and fiber count.

Once optical and electrical interfaces have been established, a thermal-mechanical support structure may be incorporated to complete the package and provide structural stability and thermal management across the full stack. This structure may serve as both a mechanical enclosure and a heat dissipation pathway, interfacing with the functional silicon and optical layers, as well as the power delivery module. In some embodiments, the support structure may include metallic frames, cold plates, heat spreaders, or vapor chambers, selected based on system-level thermal dissipation requirements and packaging constraints.

The thermal-mechanical support structure may be attached to the top and/or bottom of the package using mechanical fastening (e.g., screws or clamps), thermally conductive adhesives, or compression frame assemblies. Contact points may be thermally coupled to high-power devices such as GPUs, voltage regulators, or optical transmitters to assist in removing heat generated during operation. In some embodiments, the support structure may include integrated channels for liquid cooling, fins for passive air convection, or embedded temperature sensors for active thermal regulation. The design of the support structure may be adjusted to manage thermal expansion mismatches, mechanical stress distribution, and long-term reliability, especially in large-area panel-scale or rack-scale configurations. Variations in material composition, mechanical stiffness, and thermal conductivity may be applied depending on use case requirements.

In some embodiments, the manufacturing process for O/E chiplets may begin with formation of an epitaxial light-emitting structure suitable for high-speed optical switching. The structure may include GaN-based epitaxial layers grown on a silicon substrate and configured to implement uLEDs or other high-speed emitters. The GaN epitaxial stack may be engineered to support carrier recombination rates compatible with modulation at or above about 1 Gb/s per pixel, with material quality selected to reduce non-radiative losses and defect densities.

In some embodiments, GaN-on-Si growth may include deposition of buffer layers, n-type GaN, MQWs, p-type GaN, and optional electron-blocking and current-spreading layers. Layer thickness and composition may be tuned for target modulation speed, emission wavelength, and coupling efficiency into a downstream waveguide structure. The epitaxial wafer may then be processed to define pixel arrays, contact pads, and alignment marks, and may be prepared for hybrid bonding by depositing a planarized dielectric with recessed metal bond pads sized for wafer-to-wafer or chip-on-wafer integration. Variations in substrate type (for example, sapphire or silicon carbide) and emission bands may be selected to match system constraints and waveguide material compatibility. In some embodiments, commercially available fast switching epitaxial GaN on Silicon wafer structures may be employed in addition to or instead of the abovementioned custom epitaxial structures.

In some embodiments, following epitaxial growth, the surface may be patterned to define individual emitter or detector regions. Pixelation may be performed using photolithography and dry or wet etching to isolate discrete pixels with well-defined p-type and n-type contact regions. For uLED configurations, pixels may be arranged for electrical signal input and optical signal output, while for photodiode configurations, pixels may be arranged for optical signal input and electrical signal output.

In some embodiments, metallization may be deposited and patterned to form recessed copper pads that function as bonding and routing points for hybrid integration. The top surface of the chiplet wafer may be planarized, for example by chemical-mechanical polishing, to expose the recessed metal within a bonding-compatible dielectric such as oxide or nitride. The hybrid bond-capable surface may then be aligned and bonded to a metallized silicon wafer that may include integrated driver or TIA circuitry or may serve as a passive electrical routing platform.

In some embodiments, where driver or TIA circuitry is positioned beneath the photonic chiplet, one or more copper vias may be formed through the GaN stack to provide conductive paths for bias, modulation current, and ground directly to pixel contacts. Vertical power and signal delivery may reduce lateral trace congestion and may improve packaging density. Pixel size, spacing, and interconnect geometry may be selected based on required bandwidth, switching speed, and coupling strategy to a waveguide interface.

In some embodiments, the photonic chiplet may be hybrid bonded to a silicon substrate that does not include an integrated driver, wherein driver or TIA functions reside within a GPU or other logic device. The hybrid bond may be formed between a planarized oxide surface with recessed copper pads on the photonic chiplet and a corresponding metallized surface on the silicon wafer. After bonding, a bottom silicon handle of the photonic wafer may be removed to expose active GaN or related photonic layers. This configuration may simplify thermal management when the GPU or other logic device is positioned near a cold plate and may avoid through-silicon vias within the photonic stack, while potentially increasing redistribution-layer complexity between the GPU or other logic device and the photonic interface. In some embodiments, direct-driven light sources such as LEDs or VCSELs may be arranged such that each driver channel is associated with a respective light source pixel. In configurations where a driver circuit is hybrid bonded directly to a light source pixel array, conductive bonding pads may be arranged to provide a one-to-one electrical connection between individual driver channels and corresponding light source pixels. The driver circuit may receive input signals through through-silicon vias formed in the driver substrate, and the driver circuitry may be configured such that a given through-silicon via provides signaling to one or more light source pixels. Through-silicon vias may be coupled to RDL routing that extends toward a GPU or other logic device. The RDL routing associated with the through-silicon vias may be less dense than the bonding interface to the light source pixel array, for example due to signal multiplexing or demultiplexing performed within the driver circuitry. In some embodiments, driver circuitry may be integrated within a GPU or other logic device, and electrical connections may extend from the driver circuitry to a substrate carrying the light source pixel array. In such configurations, a plurality of electrical conductors may be routed between the GPU or other logic device and the light source pixel array to support individual control of respective pixels. The routing density beneath the GPU or other logic device may therefore differ from arrangements in which a separate driver circuit is hybrid bonded to the light source pixel array. Similar considerations may apply to configurations in which photodiodes are coupled to transimpedance amplifiers, including cases where the transimpedance amplifier circuitry is integrated with a logic device or provided as a separate circuit coupled to the photodiode array.

In some embodiments, the photonic chiplet may be hybrid bonded to a silicon substrate that includes integrated driver or TIA circuitry separate from the GPU or other logic device. The driver silicon may incorporate TSVs to support vertical power and signal routing. After bonding the photonic layer to the driver silicon, a TSV reveal process may expose contacts for subsequent bonding to a waveguide-electrical interposer. A TSV diameter of about 8 μm or smaller may be targeted; at this size, a single TSV may drive approximately ten uLED or photodiode pixels, yielding a TSV area density of approximately 0.8% within a 1 mm×7.5 mm beachfront and supporting aggregate optical interconnect densities on the order of about 10 Tb/s/mm at about 1 Gb/s per pixel. This arrangement may reduce long-distance redistribution complexity while introducing thermal management considerations for the local driver silicon.

In some embodiments, following hybrid bonding and, where applicable, TSV formation and reveal, the wafer may be diced into individual O/E chiplets that may include a uLED emitter array, a photodiode detector array, or both, with optional integrated driver or TIA circuitry depending on configuration. Photodiode wafers may be fabricated using GaN-on-Si or CMOS-compatible detector processes based on target sensitivity and bandwidth. Chiplet size, bonding-pad pitch, and thickness may be tailored for integrated-driver or driverless modes and for top-side or edge-side optical coupling. Alignment marks, fiducials, or bonding frames may be incorporated to support high-precision placement.

In some embodiments, diced uLED and photodiode chiplets may be hybrid bonded onto a prepared waveguide-electrical interposer using a chip-on-wafer process. The interposer surface may include CMP-planarized oxide with recessed copper pads to support fine-pitch hybrid bonding. Chiplets may be placed in alignment with underlying waveguide routing features and electrical interconnects to promote efficient optical coupling and vertical power and signal delivery.

In some embodiments, once chiplets are bonded to the interposer, the top surface may be configured for several integration paths. A first path may hybrid bond the surface to a wafer-level or panel-level package for direct optical and electrical interfacing with compute, memory, or co-packaged logic layers. A second path may build a polyimide-copper redistribution layer on the surface to distribute signals and power over a larger area. A third path may attach standard two-dimensional or three-dimensional packages, such as chip-on-wafer-substrates, EMIB™-based multichip modules, or Intel's FOVEROS™ devices, directly to the interposer by thermo-compression bonding, mass reflow, or hybrid bonding. For hybrid bonding, mating surfaces on both sides may include oxide with recessed metals, with room-temperature contact followed by annealing to complete metal-to-metal bonds. For thermo-compression or reflow, mating interfaces may include solder-resist or polyimide with pad openings and metal bumps or pastes.

In some embodiments, the bottom surface of the waveguide-electrical interposer may be configured to accept power-delivery modules by flip-chip attachment using mass reflow or thermo-compression bonding. The interposer may thereby function as a central interface that routes optical signals through the waveguide planes, electrical signals through metallization and redistribution layers, and power through embedded vias to compute, memory, and photonic elements. This stacked, co-packaged arrangement may support high-density, wide-parallel communication while maintaining compact form factors and compatibility with wafer-or panel-scale manufacturing flows.

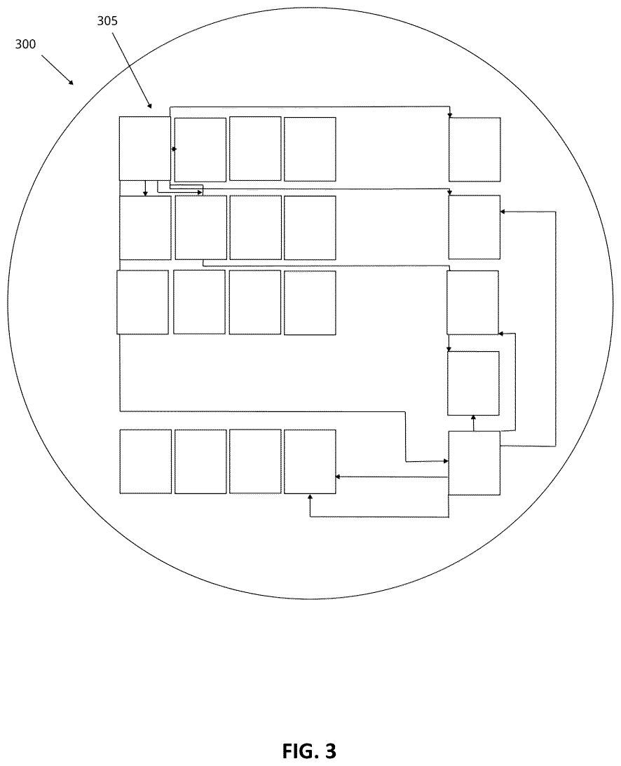

FIG. 3 illustrates, in plan view, an embodiment of a wafer-or substrate-scale compute assembly 300 including a plurality of silicon dies 305 mechanically coupled to the substrate to form a dense compute structure. In some embodiments, dies 305 may comprise processors, AI accelerators, graphics processors, memory devices, network controllers, or combinations thereof. Optical communication between selected ones of the dies 305 may be provided by one or more optical routing layers disposed in or on the substrate 300, while electrical redistribution layers may provide local power and control signaling. The arrangement shown is schematic and not to scale; die sizes, spacing, and routing paths may vary by implementation.

In some embodiments, the substrate 300 may include a semiconductor, glass, ceramic, or organic buildup base, optionally with one or more electrical RDLs and power distribution layers. Optical routing may be provided by a set of waveguide layers formed within the substrate 300 or deposited above it. The waveguide fabric may comprise a single layer or multiple stacked layers configured to support independent optical pathways between dies 305.

The waveguides may be formed from silicon nitride, silicon oxynitride, aluminum oxide, polymer dielectrics, glass, or combinations thereof, with cladding materials selected to provide index contrast suitable for low-loss guidance. In some embodiments, four or more optical layers may be employed to relieve routing congestion and to accommodate crossings without requiring sharp bends. Inter-layer optical transitions may be provided by vertical coupling structures such as tapered transitions, evanescent couplers, prism or mirror couplers, or grating-based couplers. Horizontal coupling between the waveguide fabric and on-substrate devices may use edge, vertical, or free-space coupling structures.

In some embodiments, the optical routing layers of the substrate 300, or a portion thereof, are used to provide intra-silicon communication within a single silicon die 305. For example, one or more photonic layers including laterally coupled emitters, waveguides, and detectors may be bonded to a compute die so that modulated optical signals are routed laterally between regions associated with that die through a wide parallel optical interface.

In some embodiments, the same laterally coupled photonic-layer approach supports inter-silicon communication between multiple silicon dies 305. For example, a plurality of dies may be integrated onto a photonic interposer that includes multiple layers of laterally coupled emitters, waveguides, and detectors, thereby supporting any-to-any optical connectivity among dies across a wafer-scale or reconstituted-wafer assembly. In some embodiments, lateral routing may predominate within one or more layers, while vertical routing structures may be used selectively to couple between layers or to realize specified routing permutations.

O/E transceiver functionality may be provided by chiplets positioned on, within, or adjacent to substrate 300. The chiplets may include one or more optical emitters (e.g., micro-light-emitting diodes, vertical-cavity surface-emitting lasers, quantum-dot emitters, silicon photonic modulators) and one or more optical detectors (e.g., photodiodes with or without associated transimpedance amplifiers). In some embodiments, the O/E chiplets may be hybrid bonded into recesses of the substrate or disposed under portions of dies 305 to conserve surface area while maintaining optical access to the waveguide fabric. In some embodiments, the emitters may be external to the substrate and optically coupled via fibers or free-space elements to input structures on the waveguide fabric, while detectors remain on or within substrate 300.

Electrical interconnects may be provided by RDLs patterned in metal over dielectric layers, by through-substrate vias, micro-bumps, or hybrid-bond pads. Power delivery to dies 305 and to O/E chiplets may be provided by dedicated power planes and vias within substrate 300. Thermal management structures may be included above or below the assembly, and mechanical stiffeners may be used where panel-level scaling is desired.

The optical routing topology implemented by the waveguide fabric may include all-to-all, partial mesh, hierarchical, or hybrid patterns. In other implementations, short-reach connections between neighboring dies may be electrical while longer-reach or high-fanout connections utilize optical paths. The routing may extend across wafer-scale substrates, panel-scale substrates, or across multiple substrates interconnected optically via edge or vertical ports. Optional external interfaces may be provided to couple optical signals to fibers for inter-module communication.

In some embodiments, short-reach optical links for intra-substrate communication may be established using emitters coupled into waveguides, while long-reach links may be established using sources coupled to optical fibers for inter-substrate or inter-rack communication. Coupling to the waveguide fabric may be performed by subwavelength gratings, tapered vertical couplers, or evanescent regions, and coupling to fibers may be performed by surface gratings, edge couplers, or angled ports aligned to ferrules. Link budgets may be tailored by selecting wavelength bands, coupler designs, and numerical apertures compatible with the materials stack. In some embodiments, a management function may select short-reach or long-reach paths per flow according to reach, fan-out, and power budget. Traffic classes that require extended distance or isolation may be routed to fiber egress, while local aggregation and device-to-device carriage on the same substrate may be routed through waveguide planes.

Fabrication may include forming the electrical layers of substrate 300, forming the waveguide fabric by deposition and patterning, creating inter-layer optical couplers where required, and attaching O/E chiplets and dies 305 by hybrid bonding, flip-chip, or surface-mount techniques. Alignment features may be used to position optical couplers relative to emitters and detectors. The resulting assembly may support low-latency, high-bandwidth communication among the dies 305 with reduced power consumption compared to routing that relies solely on electrical links. In some embodiments, mixed optical-electrical interconnect schemes may be applied to balance performance targets, energy use, and layout constraints.

In some embodiments, electrical-to-optical aggregation may be performed using integer multiplexing ratios (for example, 8:1 or 16:1) that map groups of electrical lanes from a die 305 to arrays of optical channels. Corresponding demultiplexing may be performed at a receiving node, and control logic may allocate channels dynamically to meet workload demands.

In some embodiments, O/E chiplets may be positioned in die-shadow regions beneath portions of dies 305 and may be received in recessed pockets of substrate 300. Optical keep-out zones, low-index trenches, or metal shields may be incorporated proximate to coupling regions to reduce parasitic coupling and electrical noise. Through-die apertures or windows may be formed where vertical optical access is desired.

In some embodiments, optical crosstalk mitigation is supported by suppressing unguided optical energy that propagates outside intended guided modes. For example, optical energy emitted by a microLED pixel or VCSEL pixel, and/or optical energy propagating within a waveguide, may include components that couple into surrounding cladding or other dielectric regions (e.g., leaky modes, radiation modes, and/or slab-like modes). Such unguided components may propagate laterally and contribute to optical coupling between adjacent waveguides, between adjacent pixels, and/or between a waveguide and a pixel outside an intended channel.

In some embodiments, a light-blocking coating is disposed around one or more optical structures to attenuate, reflect, and/or otherwise reduce propagation of the unguided components. The light-blocking coating may include one or more metal layers disposed adjacent to one or more of: a vertical coupling waveguide, a horizontal waveguide, a lens or coupling layer in an optical interface stack, and/or an optoelectronic pixel region. In some embodiments, the light-blocking coating is arranged to intercept optical energy that would otherwise enter or propagate through a cladding region surrounding a waveguide core, thereby reducing a likelihood of optical crosstalk between neighboring waveguides and/or between waveguides and pixels.

In some embodiments, the light-blocking coating includes a reflective metal configured to reflect at least a portion of the unguided optical energy back toward an emitting cavity region and/or back toward a vertical coupling waveguide. Examples of reflective metals may include aluminum, chromium, and silver. In some embodiments, reflecting unguided optical energy back toward the coupling region increases a fraction of optical energy that couples into one or more guided modes (e.g., central, lower-order modes) of a target waveguide compared to a configuration without the reflective metal.

In some embodiments, the light-blocking coating includes an absorptive metal configured to attenuate unguided optical energy by absorption. Examples of absorptive metals may include copper, nickel, cobalt, tungsten, titanium, tantalum, and vanadium. In some embodiments, absorptive metals reduce optical crosstalk by damping propagation of leakage through cladding regions, even where a reflected “recovery” component is reduced relative to a reflective-metal implementation. In some embodiments, selection between reflective and absorptive behavior is made based on one or more of process compatibility, thermal considerations, layout constraints, and channel isolation targets.

In some embodiments, the light-blocking coating includes a single metal layer. In other embodiments, the light-blocking coating includes a multi-metal stack where different layers provide different optical behaviors and/or fabrication advantages. In some embodiments, selection of a single metal versus a multi-metal stack is constrained by one or more process flows and/or design rules of the photonic fabric, including constraints associated with planarization, bonding, and reliability.

In some embodiments, the light-blocking coating is applied selectively, such that metal is placed at targeted locations where leakage and/or crosstalk is expected to be higher, rather than being applied uniformly. Example placement permutations may include metal disposed around a vertical coupling waveguide, metal disposed around a lens structure in an optical interface stack, metal disposed around a pixel region, metal disposed on one or more sidewalls of a vertical coupling waveguide, and/or metal disposed on one or more sidewalls of a horizontal waveguide. In some embodiments, a horizontal waveguide is coated on a top surface, a bottom surface, or both top and bottom surfaces. In some embodiments, a horizontal waveguide is coated along a full length, and in other embodiments the coating is limited to one or more localized regions, such as near a junction between a vertical coupling waveguide and a horizontal waveguide.

In some embodiments, the light-blocking coating covers a waveguide on all sides. In some embodiments, the coating covers only a subset of surfaces (e.g., one sidewall, two sidewalls, top only, bottom only, or top+bottom without sidewalls). In some embodiments, partial coverage is selected to satisfy fabrication constraints (e.g., deposition directionality, etch access, and/or bonding keep-outs) while still reducing cladding-mode propagation in a direction associated with crosstalk pathways.

In some embodiments, the light-blocking coating is formed on dielectric surfaces in the coupling region. For example, metal may be deposited onto a pixel passivation oxide and/or onto an oxide of a lens layer. In some embodiments, metal is deposited onto a cladding oxide adjacent a waveguide side. In some embodiments, metal is deposited onto sidewalls of a vertical coupling waveguide and optionally combined with metal on a cladding oxide region and/or metal on pixel passivation/lens oxide. In some embodiments, a horizontal waveguide includes metal on a top surface, on a bottom surface, or on both top and bottom surfaces, and may further include metal on one or more sidewalls. In some embodiments, a combination of metal on top and bottom of the horizontal waveguide and metal on vertical waveguide sidewalls is used to reduce leakage propagation through multiple layers of the stack. In some embodiments, metal is disposed in “almost everywhere” configurations, with exceptions for electrical interconnect regions, bonding regions, and/or other process-driven keep-outs.

In some embodiments, the light-blocking coating is integrated with a bonding stack between an O/E chiplet and a photonic fabric. For example, one or more metal layers may be located under one or more dielectric bonding layers. In some embodiments, metal is formed on one side of a bonding interface, followed by formation of one or more dielectric bonding layers, and dielectric bonding is performed. In some embodiments, metal is formed on both sides of the bonding interface, followed by formation of dielectric bonding layers on the respective sides, and dielectric bonding is performed. In some embodiments, the resulting bonded interface includes metal regions positioned to block or attenuate unguided optical energy in the vicinity of the coupling interface.

In some embodiments, the light-blocking coating is integrated as part of a hybrid bonding stack. For example, a metal layer may be provided at a bonding interface and recessed relative to surrounding dielectric by planarization, such that an initial bond is formed via dielectric-to-dielectric contact followed by thermal processing that promotes metallurgical bonding between opposing metal regions. In some embodiments, a process sequence includes depositing metal onto a cladding oxide and/or a passivation oxide and/or a lens oxide, forming a bonding dielectric oxide over the metal, planarizing, and bonding the O/E chiplet to the photonic fabric using the bonding dielectric, with the metal positioned to provide light-blocking behavior after bonding.

In some embodiments, the presence and placement of the light-blocking coating is verifiable in a completed structure. For example, cross-section analysis may be used to observe a location, morphology, and/or composition of metal layers relative to waveguides, cladding regions, lens/coupling layers, and/or pixel passivation layers, including for assessing whether the metal layers are present in locations configured to suppress unguided-mode propagation.

In some embodiments, built-in test and calibration features may be integrated into the optical fabric. Example features may include optical loopback paths, monitor photodiodes tapped from active waveguides, on-chip eye monitors, and electrically controlled test sources. These features may support link bring-up, drift compensation, and in-field diagnostics.

In some embodiments, fault tolerance may be supported by spare waveguide paths, spare wavelengths, or reconfigurable elements that reroute around localized defects. Control firmware or software may manage path selection, wavelength assignment, etc. to maintain optimal performance.

In some embodiments, thermal management for the optical layers may include localized thermal spreaders, thermal isolation trenches around resonant devices, and closed-loop bias control using monitor signals to stabilize output power and wavelength. Current drivers and TIAs associated with O/E chiplets may include power gating or dynamic biasing to reduce idle power.

In some embodiments, external optical coupling (when used) may be facilitated by alignment fiducials, etched guide features, or micro-lens arrays that interface with fiber arrays or free-space optics. Passive or active alignment strategies may be employed, and coupling structures may be designed to tolerate lateral and vertical misalignments within selected bounds.

In some embodiments, a control plane may coordinate optical resource management across substrate 300, including wavelength assignment, channel scheduling, and link calibration. Telemetry from monitor elements may be collected to adapt routing and modulation formats to workload and environmental conditions.

In some embodiments, telemetry features may include monitor photodiodes coupled to active waveguides, tap couplers for out-of-band power measurements, and per-lane error counters within electrical interfaces. Calibration routines may adjust emitter bias, detector gain, resonant-coupler trims, and wavelength assignments in response to the telemetry. Thresholds may be defined for optical power, error rate, and temperature so that corrective actions may be applied before margins are exceeded.

In some embodiments, resiliency may be provided by spare waveguide paths, spare wavelengths, or standby connections. When a monitored metric crosses a threshold, a protection controller may migrate flows to spare resources, adjust multiplexing ratios at an optical-electrical boundary, or modify routing to maintain target service levels. Background calibration may be scheduled to reduce disruption to active traffic.

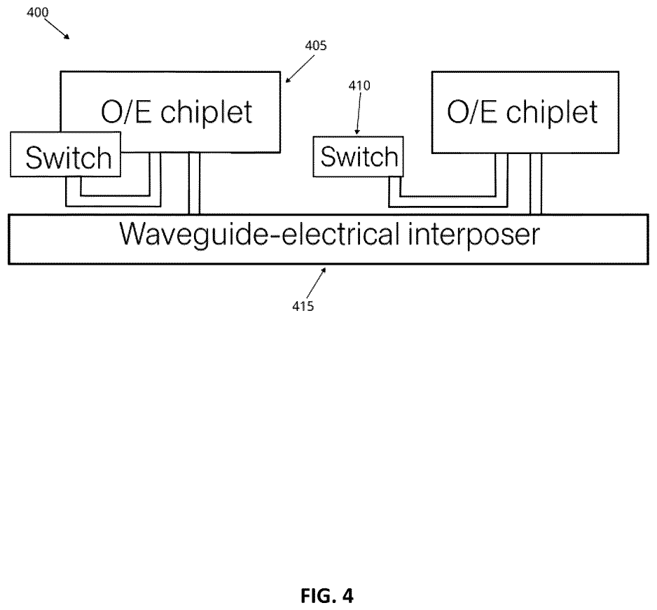

FIG. 4 illustrates an interconnect architecture 400 in which O/E chiplets 405 and switches 410 are integrated on a waveguide-electrical interposer 415. The O/E chiplets 405 may include optical emitters and detectors, such as micro-LEDs, VCSELs, or photodiodes, configured to perform electrical-to-optical and optical-to-electrical conversion. By incorporating these chiplets directly onto the interposer 415, the system may support efficient optical communication between multiple switching layers within a package.

The switches 410 may be coupled to the O/E chiplets through short, wide electrical interfaces, supporting low-latency data transfer and high aggregate bandwidth. In some embodiments, the switches may perform packet routing, multiplexing, or crossbar switching to manage traffic between optical channels.

The waveguide-electrical interposer 415 may include both optical waveguides and electrical redistribution layers, allowing signals to be routed optically across longer distances, for example between switching layers in a multi-tier topology, while maintaining short electrical paths for local connections. This integration may reduce power consumption, mitigate signal integrity issues, and increase routing density compared to interposers relying solely on electrical wiring.

The switching architecture 400 may be replicated across a wafer-or panel-scale substrate, forming a scalable switching fabric capable of supporting mesh, all-to-all, or hierarchical topologies for high-performance computing and data movement.

In some embodiments, a high-radix switching fabric may be implemented on a wafer-scale substrate (WSS), consolidating switching resources to reduce cabinet footprint and power associated with distributed deployments. The WSS may include both electrical and optical layers, with waveguide-based optical routing on the waveguide-electrical interposer 415 carrying longer-reach, high-bandwidth paths and electrical layers handling short-reach local connections. Consolidation onto a single WSS may facilitate substantial reductions in cabinet area allocated to switching while simplifying cabling and serviceability.

In some embodiments, more than one switching layers may be integrated within the same WSS to support multi-tier topologies, for example in intra-cabinet connectivity and scale-out connectivity across cabinets. The scalability of the fabric may be parameterized by N and M, where N denotes the scale-up domain for intra-cabinet interconnects and M denotes the scale-out domain for inter-cabinet links; parameters k and X may be selected so that aggregate intra-cabinet capacity N·k·X may exceed inter-cabinet demand M·(X/2) for targeted workloads. Integrating both layers may eliminate separate external switch ASICs and long-reach electrical trunks, which may reduce latency and energy per bit while preserving high bandwidth.

In some embodiments, an O/E chiplet-based interposer may be incorporated within the WSS to provide optical routing between switching layers via waveguide interconnects on the interposer 415. The O/E chiplets 405 may include photodiodes, micro-LEDs, VCSELs, silicon-photonics modulators, or combinations thereof, and may connect to switches 410 over wide, short-reach electrical interfaces. Optical carriage of inter-layer traffic on the interposer 415 may avoid long electrical runs and associated equalization overheads, supporting dense, wide-parallel links at low energy per bit.

In some embodiments, integer multiplexing at the O/E interface may be used to bridge data-rate mismatches and reduce serializer overhead. Ratios such as 8:1, 10:1, or 16:1 may map groups of electrical lanes from a switch 410 onto arrays of optical channels in O/E chiplets 405, with complementary demultiplexing at a receiving node. This approach may preserve low-latency conversion while reducing reliance on deep SERDES stacks.

In some embodiments, a purely electrical interposer variant may route L1↔L2 connections exclusively through electrical paths on the WSS. High-speed SERDES interfaces on the switches 410 may drive connectors embedded in the electrical routing layers, and flyover cable assemblies may be used where signal crossings exceed practical board routing limits at the desired rates. Where optical reach is required, O/E chiplets 405 positioned at strategic interconnect points may convert between electrical and optical domains, forming parallel fiber bundles for intra-or inter-cabinet links and reconverting at destination switches or compute devices.

In some embodiments, a wafer-scale switching substrate may co-locate first-level switching resources that serve intra-enclosure links and second-level switching resources that serve scale-out links on the same substrate. Local electrical interfaces may couple each switch device to proximate opto-electronic interfaces, while optical pathways in a stacked waveguide fabric may carry traffic between the first-level and second-level switching layers across longer on-substrate distances. Port assignment, forwarding, and link calibration may be coordinated by a control plane so that packet flows select optical pathways for extended reaches and short electrical paths for local aggregation.

In some embodiments, the optical pathways used for inter-layer carriage may include one or more planes of waveguides with vertical transitions, mode transformers, or reflective turning elements to establish routes between switching layers. The arrangement may support arbitrary network topologies such as mesh, folded-Clos, or hierarchical patterns, and may expose optical egress at a top surface or an edge for connection to fiber assemblies when inter-substrate communication is desired.

In some embodiments, external optical interfaces may be incorporated for direct to GPU and second level network connections. When the interposer 415 provides waveguide routing with O/E chiplets 405, these connections may be implemented as wide-parallel optical interfaces, allowing the switches 410 to communicate with the O/E chiplets 405 over wide parallel electrical links that are converted to wide-parallel optical signals before exiting the WSS. The optical signals may be routed through fiber plug-in connectors and delivered as high-density fiber bundles to peer switches or compute nodes, where O/E chiplets may reconvert the signals to electrical form.

In some embodiments, the substrate may include plug-in fiber interfaces aligned to optical ports of the waveguide stack at a top surface or an edge. The interfaces may include ferrule pockets, alignment fiducials, and adhesive keep-out regions compatible with optical materials, and may support connector formats with standardized fiber counts. Coupling elements at the ports may include surface gratings, micro-lenses, prism couplers, or polished facets, with geometries selected to accommodate bend-radius constraints and packaging height. In some embodiments, the plug-in interfaces may be organized into fields that correspond to port groups in the switching fabric, allowing cable harnesses to be dressed along thermal and airflow pathways. The interface geometry, connector type, and port pitch may be selected to balance service access, density, and optical loss targets.

In some embodiments, a wafer-scale switching architecture may be realized without waveguide layers on the interposer 415, relying instead on high-density SERDES links for all paths. The electrical-only interposer may employ fine-pitch features and controlled-impedance routing to sustain lane counts required for high-radix operation within a compact footprint.

In some embodiments, connector density may be increased by clam shelling connectors on both sides of the WSS, raising aggregate lane count per rack unit while maintaining service access. Pluggable photonic integrated circuit (PIC) modules may be positioned above connector footprints to support optional electrical-to-optical SERDES conversion for long-reach links. The PIC modules may incorporate electro-optic modulators (for example, Mach-Zehnder interferometers or micro-ring modulators) and photodetectors to support bidirectional conversion at the external interfaces.

In some embodiments, the switches 410 may drive SERDES signals to the connector fields, where signals may either egress directly as electrical lanes or be converted to optical form via the pluggable PIC modules for extended reach. The choice of direct electrical egress versus local E/O conversion may be determined by distance, loss budget, and port utilization objectives, and may be configurable at deployment.

In some embodiments, these switching, conversion, and routing elements may be tiled across the interposer 415 to realize high-radix fabrics. Tile pitch, ports per tile, and the optic-to-electric ratio may be selected to satisfy bandwidth and latency targets while observing thermal and power-delivery constraints.

In some embodiments, a custom compute block may be vertically stacked beneath the WSS to provide integrated switch-control processing. The complex may include one or more processors with local memory and may execute control-plane functions such as packet-forwarding management, routing-table updates, telemetry collection, load balancing, admission control, and firmware orchestration for the switches 410 and the O/E chiplets 405. Electrical interfaces to the switches 410 may use short-reach die-to-die links through the interposer 415 with controlled-impedance RDL paths and sideband management links for low-latency register access.

In some embodiments, the compute complex may be connectorized to the WSS using industry interfaces such as PCIe or CXL on a mezzanine or sled. This arrangement may provide low-latency DMA paths into the switch silicon while supporting out-of-band management through Ethernet control ports for remote configuration, monitoring, and updates. Field replaceability and upgrades may be supported without disturbing the remainder of the WSS.

In some embodiments, the compute complex may distribute time-synchronization and security services for the fabric. Precision time signals may be fanned out to the switches 410 and accessible through the O/E chiplets 405 to coordinate timestamping or time-slot allocation. Secure-boot, measured-boot, device attestation, and key management may be implemented, and telemetry agents may read per-lane error counters in the switches 410, optical power monitors exposed via the O/E chiplets 405, and temperature/voltage sensors proximate to critical circuits on the interposer 415 to drive policy-based rerouting, rate shaping, or wavelength reassignment.

In some embodiments, a control processor complex may be integrated with the switching substrate to provide switch management, topology discovery, link calibration, and telemetry processing. The complex may include one or more processors, local memory, and non-volatile storage, and may communicate with switch devices and opto-electronic interfaces over short-reach interconnects. Time synchronization, device attestation, and firmware services may be hosted by the control processor complex so that routing tables, wavelength assignments, and protection policies may be updated during operation. In some embodiments, the control processor complex may be vertically stacked with the switching substrate or attached through standardized board-level connectors. Placement may be selected to meet thermal constraints and service requirements, and power domains may be partitioned so that control-plane functions remain available during data-plane reconfiguration.

In some embodiments, thermal and power delivery for the compute complex may be co-designed with the WSS. A common cold plate may be shared with the switches 410, or a dedicated heat spreader may be attached using standoffs and thermally conductive interface materials. Power domains may be isolated from high-swing I/O rails of the switches 410, with decoupling near high di/dt blocks and stitched planes within the interposer 415 to reduce impedance and noise coupling.

In some embodiments, multiple WSS units may be interconnected to increase radix and aggregate capacity. Where the interposer 415 incorporates waveguide routing with the O/E chiplets 405, inter-WSS connections may be implemented as wide-parallel optical links carried over fiber bundles that egress the WSS via plug-in connectors; the receiving WSS may reconvert signals for handoff to the switches 410. Where the interposer 415 is electrical-only, inter-WSS connectivity may use high-density SERDES lanes routed to clamshelled connector fields on opposing faces of the WSS, with optional on-board pluggable photonic modules providing electrical-to-optical conversion for extended reach.

In some embodiments, the compute complex may coordinate multi-WSS operation by managing topology discovery, link bring-up, protection switching, and traffic-class policies across multi-tier resources. Integer multiplexing control for the O/E chiplets 405 may be managed centrally, and spare-path activation may be triggered when monitored error rates or optical power margins cross thresholds. High-availability configurations may deploy dual compute complexes with state replication to support hitless failover.

In some embodiments, multiple switching substrates may be arranged in an array within a tray or chassis, with inter-substrate links provided by wide-parallel fiber bundles or by high-density electrical lanes, depending on the interposer configuration. Inter-substrate links may preserve traffic classes and policies used within each substrate so that the switching hierarchy scales without changes to forwarding behavior. Mechanical features may include alignment pins, strain-relief features for fiber management, and thermal standoffs compatible with cold plates or heat spreaders.

In some embodiments, a control plane may coordinate link bring-up and topology maintenance across the array. Discovery, address assignment, and protection switching may be performed so that additional substrates may be added or replaced while maintaining target bandwidth and latency characteristics.

In some embodiments, the compute complex may be realized as a chiplet directly on the interposer 415, as a vertically stacked module beneath the WSS, or as a removable card attached through board-level connectors. The selection among these placements may be based on latency targets, serviceability, cooling strategy, and supply-chain partitioning while maintaining software compatibility for control-plane services and management tooling.

In some embodiments, a switching substrate may support both short-reach and long-reach optical connectivity within a common packaging platform. Short-reach paths may use on-substrate emitters coupled into waveguides for intra-substrate communication, where emitters may include micro-light-emitting diodes, silicon-photonic modulators, or quantum-dot emitters aligned to surface gratings, tapered vertical couplers, evanescent regions, or reflective turning elements formed in the waveguide stack. Long-reach paths may use sources coupled to optical fibers for inter-substrate or inter-cabinet communication, where sources may include VCSEL arrays or externally pumped devices routed through fiber connectors. Link budgets may be set by waveguide propagation loss, coupler efficiency, fiber coupling loss, and device output power, and may be tailored by selecting wavelength bands, polarization states, and numerical apertures appropriate for the materials stack.

In some embodiments, compute or switch elements may incorporate a first optical interface coupled to waveguides for local links and a second optical interface coupled to optical fibers for extended links, such that any element may communicate with any other element on-substrate or off-substrate without reliance on long electrical traces. Port mapping may associate groups of electrical lanes with specific local and extended optical ports, and a control plane may allocate paths according to reach, fan-out, and congestion state. Forwarding tables, credit-based flow control, and load-balancing policies may be applied to choose between waveguide routes and fiber egress for a given traffic class.

In some embodiments, optical bandwidth densities on the order of about 10 terabits per second per millimeter and energy per bit on the order of about 1 picojoule per bit or less may be targeted for selected configurations. These figures may assume per-pixel modulation on the order of about 1 gigabit per second with waveguide pitches near the sub-micrometer range, coupler insertion losses within selected bounds, and thermal designs that maintain emitter and detector bias points within calibrated windows. Aggregate capacity may be increased by spatial parallelism across waveguides, by wavelength-division multiplexing across assigned bands, and by modest increases in per-channel symbol rates where link budgets permit.

In some embodiments, an intra-substrate optical link may be realized using on the order of thousands of micro-emitters each operating at about 1 gigabit per second and coupled to corresponding waveguides through compact couplers with footprints on the order of a few tens of micrometers. In some embodiments, an inter-substrate link may be realized using on the order of hundreds of fiber-coupled sources aggregated into multi-fiber connectors, with fiber counts selected from common arrays (for example, 12, 16, 24, or higher) or implemented using multi-core fibers. Counts and rates may be selected based on channel spacing, wavelength plans, permissible bend radii, and system-level fan-out requirements.

In some embodiments, integer multiplexing ratios such as 8:1, 10:1, or 16:1 may be applied at optical-electrical interfaces to map groups of electrical lanes to arrays of optical channels with complementary demultiplexing at a receiving node. Clocking may employ lane-group phase alignment with local clock generation and short-reach retiming. Training sequences may set pre-emphasis, threshold, and bias points for the transmit and receive elements, and optional forward-error correction with low overhead may be applied where reach or wavelength plans justify it. This approach may reduce reliance on deep serializer/deserializer stacks for the targeted distances while preserving low conversion latency.

In some embodiments, integer multiplexing may be applied at an optical-electrical interface to map groups of electrical lanes to arrays of optical channels according to a selectable ratio. Lane groups may share a local timing reference, and phase alignment may be performed across the group prior to conversion. Complementary de-multiplexing may be performed at a receiving node, and calibration sequences may set transmitter bias, receiver thresholds, and coupler trims. This approach may permit rate adaptation and lane consolidation at the interface while maintaining low conversion latency. In some embodiments, the multiplexing ratio may be selected based on available pixel count, modulation format, wavelength plan, and aggregate port bandwidth. Control logic may reconfigure the mapping in response to workload or health telemetry so that channel utilization remains within targeted margins.

In some embodiments, connections between hierarchical switching layers may be routed optically within a waveguide stack for longer internal distances, with egress provided at top-side or edge-side optical ports to fiber bundles for cabinet-level or rack-level interconnects. Port locations may be selected to balance fiber management and thermal paths, and optical interfaces may include surface gratings aligned to ferrules, edge couplers aligned to polished facets, or angled couplers aligned to recessed windows. Short electrical paths may be preserved between each switch device and its proximate optoelectronic interface to reduce equalization overhead and maintain timing margins.

In some embodiments, multiple switching substrates may be tiled within a tray or chassis and interconnected by wide-parallel optical links to form a scalable multi-substrate fabric. Inter-substrate links may preserve traffic classes and routing policies used within a substrate, and a management plane may coordinate link bring-up, topology discovery, and protection switching across the array. Mechanical features may include alignment pins, strain-relief anchors for fiber bundles, and thermal standoffs sized for uniform contact with cold plates or heat spreaders.

In some embodiments, switching and routing patterns may include 2d mesh, folded-Clos and other applicable topologies, and device options may include micro-light-emitting diodes, vertical-cavity surface-emitting lasers, quantum-dot emitters, and silicon-photonic modulators with photodiode receivers. Wavelength plans may span visible through near-infrared bands matched to waveguide materials such as silicon nitride, silicon oxynitride, polymer dielectrics, or glass. Coupling structures may be implemented as subwavelength gratings, tapered vertical couplers, evanescent sections, or reflective elements, and interfaces may be positioned at a top surface, an edge, or an angled facet according to packaging and fiber-management constraints.

In some embodiments, monitor photodiodes, tap couplers, and per-lane error counters may supply telemetry for link calibration and health assessment during bring-up and in operation. Control software may adjust emitter bias, detector gain, resonant coupler trims, or wavelength assignments to compensate for thermal drift, aging, or environmental variation. Spare paths or spare wavelengths may be provisioned to allow rapid traffic migration when monitored margins cross thresholds, and background calibration may be scheduled to avoid service disruption.

In some embodiments, the optical fabric may be applied beyond switching to provide disaggregated I/O between integrated circuit dies, memory modules, and accelerator devices. Direct photonic I/O may be established from a compute element to external modules through fiber bundles, while waveguide layers may provide local fan-out within a package. Similar packaging approaches may be used for optical backplanes in storage, memory pooling, or data-ingress applications, with the same waveguide stack routing local paths and fiber interfaces carrying extended-reach links across enclosures.

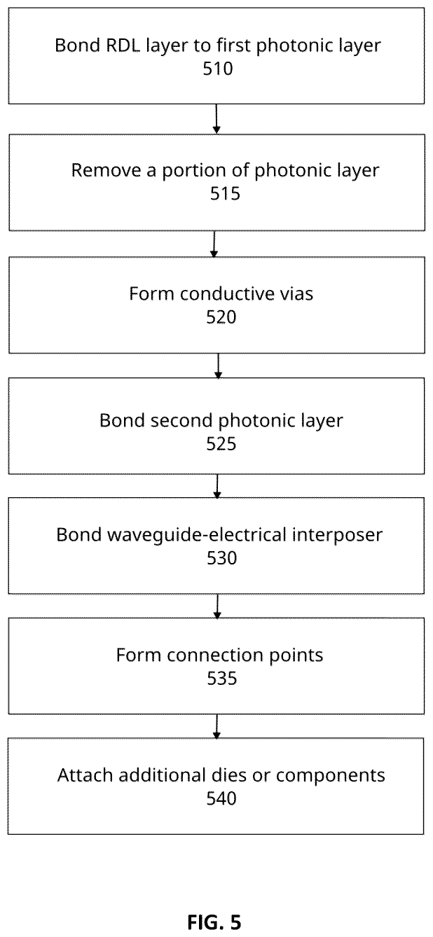

FIG. 5 illustrates, in flow diagram form, a method 500 of fabricating a multi-layer waveguide interposer structure. The process may include sequential bonding steps, substrate removal, via formation, interposer integration, and attachment of system components. The steps illustrated in FIG. 5 are exemplary, and in some embodiments the steps may be performed in a different order, in parallel, or with additional steps not expressly depicted.

At step 510, in some embodiments, a wafer comprising an electrical redistribution layer (RDL) may be bonded to a wafer comprising a first photonic layer. The first photonic layer may include an array of optical emitter structures or photodetector structures that may be configured for optical coupling to waveguides through grating couplers, tapered transitions, evanescent couplers, or reflective coupling structures. At step 515, in some embodiments, at least a portion of a handle substrate of the first photonic layer may be removed to expose the photonic layer for subsequent integration. The removal may be carried out by thinning, grinding, etching, chemical-mechanical polishing, or combinations of these techniques. At step 520, in some embodiments, conductive vias may be formed through the first photonic layer to electrically connect the photonic layer to the redistribution layer. The vias may comprise copper or other conductive materials and may, in some embodiments, have a pitch of about 10 micrometers or less to support dense interconnection.

At step 525, in some embodiments, a second photonic wafer may be bonded to the structure. The second photonic wafer may include an array of optical emitter or photodetector devices, and at least a portion of its handle substrate may be removed to expose the second photonic layer for integration. At step 530, in some embodiments, a waveguide-electrical interposer may be bonded to the assembly. The interposer may include two or more stacked optical waveguide layers that may provide independent optical routing pathways, as well as electrical redistribution layers for electrical signaling. At step 535, in some embodiments, external connection features may be formed on a surface of the interposer. These external connection features may include hybrid bonding pads, solderable micro-bumps, ball grid array (BGA) contacts, or other interconnect structures that may be configured for electrical and optical input/output. At step 540, in some embodiments, one or more additional dies or system components may be attached to the bonding surface of the interposer. These components may include integrated circuit dies such as processors or AI accelerators, memory dies such as high-bandwidth memory, or power regulation components. In some embodiments, at least a portion of the attached dies may overlie the photonic or waveguide layers while still maintaining access to the optical and electrical fabric.

In some embodiments, the method 500 may be adapted to integrate additional photonic layers, employ different bonding techniques such as oxide-to-oxide bonding, metal-to-metal bonding, or polymer bonding, or incorporate different waveguide materials and device types. In some embodiments, certain steps may be repeated or omitted depending on system design requirements.

In some embodiments, the process may begin by preparing a top wafer that includes an electrical stack (for example, a redistribution-layer wafer, a through-silicon-via wafer, an active driver or TIA wafer, a GPU driver wafer, or a passive electrical interposer) and a bottom wafer that includes a first photonic layer (for example, a pixelated emitter layer or a photodetector layer). Surfaces may be planarized by chemical-mechanical polishing and cleaned using wet or plasma activation to promote bonding. In some embodiments, bond interfaces may include oxide-oxide bonds, metal-metal bonds such as Cu—Cu thermo-compression, polymer-assisted bonds, or combinations thereof. Alignment may be achieved using infrared alignment through silicon, frontside fiducials, or embedded alignment marks. A pre-bond at room temperature may be followed by a low-or moderate-temperature (e.g., less than 400 C) anneal selected to respect device thermal budgets and to complete the bond. In some embodiments, room temperature pre-bond may allow dielectric bonding whereas the anneal allows copper recessed pads to expand due to high temperatures and bond.

In some embodiments, at least a portion of a handle substrate associated with the bonded photonic wafer may be removed to expose the active photonic structures for subsequent processing. Mechanical thinning, grinding, and stress-relief polishing may be followed by selective etching to a stop layer (for example, an oxide or nitride). Temporary carriers or bonding tapes may be used to limit bow and maintain planarity. Cleaning sequences may remove residual slurry, polymers, or native oxides while preserving device passivation. Thickness mapping and interferometric metrology may verify remaining film stacks before continuing.

In some embodiments, vertical interconnects may be formed to electrically connect the first photonic layer to the electrical stack. Via openings may be patterned by reactive-ion etching through dielectric stacks, by deep reactive-ion etching in silicon, or by laser ablation in polymer dielectrics. Insulating liners (for example, SiO₂ or SiN) and barrier/seed stacks (for example, Ti/TaN/Cu) may be deposited before copper electrofill. Planarization may be performed to clear overburden and provide a flat surface for subsequent bonding. Via pitches may be about 10 μm or less where dense biasing or signaling is desired. In some embodiments, keep-out distances may be observed around optical cores of waveguides to reduce scattering and absorption from metal proximity.

In some embodiments, a second photonic wafer may be bonded to the stack. The second wafer may comprise an emitter layer or a detector layer, and the bonding order may be selected based on material systems and routing convenience. When photodiodes are implemented in silicon CMOS, a sequence in which the detector layer is bonded before the emitter layer may simplify contact formation; when photodiodes are implemented in GaN-on-Si, either bonding order may be used. Protective passivation and planarization may be applied to the first photonic surface before the second bond. After bonding, at least a portion of the second handle substrate may be removed using a thinning and etch-back flow similar to step 515. Where required, an additional via formation sequence may be used to connect the second photonic layer to the electrical stack, with thermal budgets chosen to protect previously bonded devices. Optional top-side thinning may be applied to improve thermal resistance and mechanical compliance.

In some embodiments, a waveguide-electrical interposer may be bonded to the photonic stack. The interposer may include four or more stacked optical waveguide layers configured for independent optical routing pathways and one or more electrical redistribution layers. Optical interfaces on the interposer (for example, subwavelength grating couplers, tapered vertical couplers, evanescent coupling regions, or reflective turning elements) may be aligned to apertures or emission/receive planes of the photonic devices using optical or through-wafer alignment marks. Bond choices may again include oxide-oxide, Cu—Cu, or polymer-assisted interfaces, with post-bond anneals tailored to maintain waveguide index control and device integrity. In some embodiments, an additional electrical interposer may be bonded to the opposite face of the waveguide stack to augment power distribution or signal breakout.

In some embodiments, external connection features may be fabricated to provide system I/O and power delivery. Under-bump metallization (for example, Ni/Au or Ni/Pd/Au), copper pillars, micro-bumps, or ball-grid-array contacts may be defined with solder-mask or non-solder-mask-defined pad stacks. Reflow profiles may be selected to control wetting and coplanarity. Test pads may be included for bring-up and wafer sort. Where optical egress is desired, arrays of surface gratings, micro-lenses, prism couplers, or edge couplers may be patterned and aligned to fiber attach features. Mechanical alignment aids (for example, etched ferrule pockets or fiducials) and adhesives compatible with the optical materials may be used to stabilize fiber arrays or micro-optic assemblies.

In some embodiments, additional dies or components may be attached to the bonding surface of the interposer using chip-on-wafer hybrid bonding, flip-chip attach, or surface-mount assembly. Components may include compute dies such as GPUs or CPUs, memory stacks such as HBM, and power regulation devices such as voltage regulators, inductors, or capacitors. Known-good-die screening may be applied before placement. Decoupling capacitors may be positioned near high-di/dt consumers, and dedicated power planes and vias within the stack may be used to reduce impedance. Thermal interface materials, heat spreaders, lids, or cold plates may be added to manage junction temperatures. Underfills or compliant gap-fills may be applied to control mechanical stress. Electrical and optical test may include loopback paths, monitor photodiodes, and boundary-scan to validate continuity and link margins before singulation or final package assembly.

In some embodiments, interim inspection may include bond-strength sampling, void detection by acoustic microscopy, and optical loss measurements using on-chip test ports. Design choices may permit dicing into chiplets before bonding to a full waveguide-interposer wafer, or bonding at full wafer scale followed by dicing. Alternative flows may incorporate monolithic formation of emitters and detectors in the interposer stack, flip-chip assembly of discrete photonic die onto prepared pads, or micro-transfer printing of emitter and detector arrays followed by local metallization and passivation.

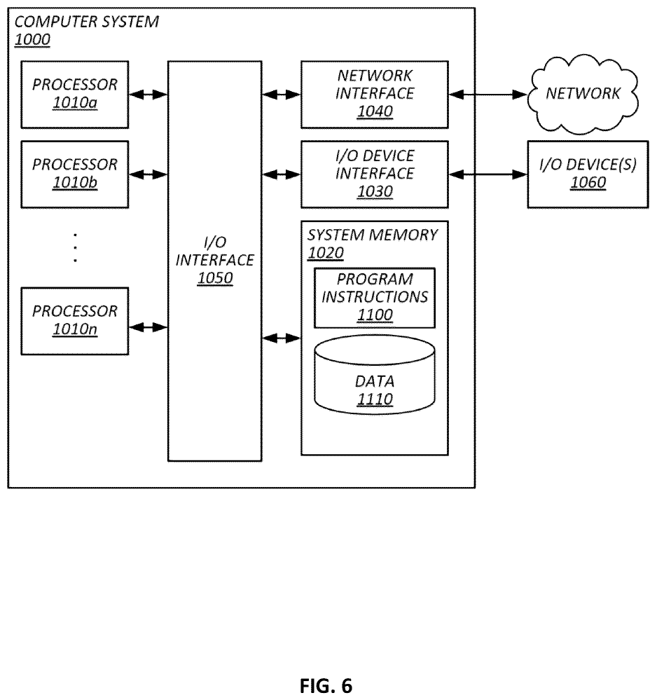

FIG. 6 illustrates an exemplary computing system 1000 in accordance with embodiments of the present technique. A single computing device is shown, but some embodiments of a computer system may include multiple computing devices that communicate over a network, for instance in the course of collectively executing various parts of a distributed application. Various portions of systems and methods described herein, may include or be executed on one or more computer systems similar to computing system 1000. Further, processes and modules described herein may be executed by one or more processing systems similar to that of computing system 1000.

Computing system 1000 may include one or more processors (e.g., processors 1010a-1010n) coupled to system memory 1020, an input/output I/O device interface 1030, and a network interface 1040 via an input/output (I/O) interface 1050. A processor may include a single processor or a plurality of processors (e.g., distributed processors). A processor may be any suitable processor capable of executing or otherwise performing instructions. A processor may include a central processing unit (CPU) that carries out program instructions to perform the arithmetical, logical, and input/output operations of computing system 1000. A processor may execute code (e.g., processor firmware, a protocol stack, a database management system, an operating system, or a combination thereof) that creates an execution environment for program instructions. A processor may include a programmable processor. A processor may include general or special purpose microprocessors. A processor may receive instructions and data from a memory (e.g., system memory 1020). Computing system 1000 may be a uni-processor system including one processor (e.g., processor 1010a), or a multi-processor system including any number of suitable processors (e.g., 1010a-1010n). Multiple processors may be employed to provide for parallel or sequential execution of one or more portions of the techniques described herein. Processes, such as logic flows, described herein may be performed by one or more programmable processors executing one or more computer programs to perform functions by operating on input data and generating corresponding output. Processes described herein may be performed by, and apparatus can also be implemented as, special purpose logic circuitry, e.g., an FPGA (field programmable gate array) or an ASIC (application specific integrated circuit). Computing system 1000 may include a plurality of computing devices (e.g., distributed computer systems) to implement various processing functions.

I/O device interface 1030 may provide an interface for connection of one or more I/O devices 1060 to computer system 1000. I/O devices may include devices that receive input (e.g., from a user) or output information (e.g., to a user). I/O devices 1060 may include, for example, graphical user interface presented on displays (e.g., a cathode ray tube (CRT) or liquid crystal display (LCD) monitor), pointing devices (e.g., a computer mouse or trackball), keyboards, keypads, touchpads, scanning devices, voice recognition devices, gesture recognition devices, printers, audio speakers, microphones, cameras, or the like. I/O devices 1060 may be connected to computer system 1000 through a wired or wireless connection. I/O devices 1060 may be connected to computer system 1000 from a remote location. I/O devices 1060 located on remote computer system, for example, may be connected to computer system 1000 via a network and network interface 1040.

Network interface 1040 may include a network adapter that provides for connection of computer system 1000 to a network. Network interface 1040 may may facilitate data exchange between computer system 1000 and other devices connected to the network. Network interface 1040 may support wired or wireless communication. The network may include an electronic communication network, such as the Internet, a local area network (LAN), a wide area network (WAN), a cellular communications network, or the like.

System memory 1020 may be configured to store program instructions 1100 or data 1110. Program instructions 1100 may be executable by a processor (e.g., one or more of processors 1010a-1010n) to implement one or more embodiments of the present techniques. Instructions 1100 may include modules of computer program instructions for implementing one or more techniques described herein with regard to various processing modules. Program instructions may include a computer program (which in certain forms is known as a program, software, software application, script, or code). A computer program may be written in a programming language, including compiled or interpreted languages, or declarative or procedural languages. A computer program may include a unit suitable for use in a computing environment, including as a stand-alone program, a module, a component, or a subroutine. A computer program may or may not correspond to a file in a file system. A program may be stored in a portion of a file that holds other programs or data (e.g., one or more scripts stored in a markup language document), in a single file dedicated to the program in question, or in multiple coordinated files (e.g., files that store one or more modules, sub programs, or portions of code). A computer program may be deployed to be executed on one or more computer processors located locally at one site or distributed across multiple remote sites and interconnected by a communication network.

System memory 1020 may include a tangible program carrier having program instructions stored thereon. A tangible program carrier may include a non-transitory computer readable storage medium. A non-transitory computer readable storage medium may include a machine readable storage device, a machine readable storage substrate, a memory device, or any combination thereof. Non-transitory computer readable storage medium may include non-volatile memory (e.g., flash memory, ROM, PROM, EPROM, EEPROM memory), volatile memory (e.g., random access memory (RAM), static random access memory (SRAM), synchronous dynamic RAM (SDRAM)), bulk storage memory (e.g., CD-ROM and/or DVD-ROM, hard-drives), or the like. System memory 1020 may include a non-transitory computer readable storage medium that may have program instructions stored thereon that are executable by a computer processor (e.g., one or more of processors 1010a-1010n) to cause the subject matter and the functional operations described herein. A memory (e.g., system memory 1020) may include a single memory device and/or a plurality of memory devices (e.g., distributed memory devices). Instructions or other program code to provide the functionality described herein may be stored on a tangible, non-transitory computer readable media. In some cases, the entire set of instructions may be stored concurrently on the media, or in some cases, different parts of the instructions may be stored on the same media at different times.

I/O interface 1050 may be configured to coordinate I/O traffic between processors 1010a-1010n, system memory 1020, network interface 1040, I/O devices 1060, and/or other peripheral devices. I/O interface 1050 may perform protocol, timing, or other data transformations to convert data signals from one component (e.g., system memory 1020) into a format suitable for use by another component (e.g., processors 1010a-1010n). I/O interface 1050 may include support for devices attached through various types of peripheral buses, such as a variant of the Peripheral Component Interconnect (PCI) bus standard or the Universal Serial Bus (USB) standard.

Embodiments of the techniques described herein may be implemented using a single instance of computer system 1000 or multiple computer systems 1000 configured to host different portions or instances of embodiments. Multiple computer systems 1000 may provide for parallel or sequential processing/execution of one or more portions of the techniques described herein.

Those skilled in the art will appreciate that computer system 1000 is merely illustrative and is not intended to limit the scope of the techniques described herein. Computer system 1000 may include any combination of devices or software that may perform or otherwise provide for the performance of the techniques described herein. For example, computer system 1000 may include or be a combination of a cloud-computing system, a data center, a server rack, a server, a virtual server, a desktop computer, a laptop computer, a tablet computer, a server device, a client device, a mobile telephone, a personal digital assistant (PDA), a mobile audio or video player, a game console, a vehicle-mounted computer, or a Global Positioning System (GPS), or the like. Computer system 1000 may also be connected to other devices that are not illustrated, or may operate as a stand-alone system. In addition, the functionality provided by the illustrated components may in some embodiments be combined in fewer components or distributed in additional components. Similarly, in some embodiments, the functionality of some of the illustrated components may not be provided or other additional functionality may be available.

Those skilled in the art will also appreciate that while various items are illustrated as being stored in memory or on storage while being used, these items or portions of them may be transferred between memory and other storage devices for purposes of memory management and data integrity. In some embodiments, some or all of the software components may execute in memory on another device and communicate with the illustrated computer system via inter-computer communication. Some or all of the system components or data structures may also be stored (e.g., as instructions or structured data) on a computer-accessible medium or a portable article to be read by an appropriate drive, various examples of which are described above. In some embodiments, instructions stored on a computer-accessible medium separate from computer system 1000 may be transmitted to computer system 1000 via transmission media or signals such as electrical, electromagnetic, or digital signals, conveyed via a communication medium such as a network or a wireless link. Various embodiments may further include receiving, sending, or storing instructions or data implemented in accordance with the foregoing description upon a computer-accessible medium. Accordingly, the present techniques may be practiced with other computer system configurations.

In block diagrams, illustrated components are depicted as discrete functional blocks, but embodiments are not limited to systems in which the functionality described herein is organized as illustrated. The functionality provided by each of the components may be provided by software or hardware modules that are differently organized than is presently depicted, for example such software or hardware may be intermingled, conjoined, replicated, broken up, distributed (e.g. within a data center or geographically), or otherwise differently organized. The functionality described herein may be provided by one or more processors of one or more computers executing code stored on a tangible, non-transitory, machine readable medium. In some cases, notwithstanding use of the singular term “medium,” the instructions may be distributed on different storage devices associated with different computing devices, for instance, with each computing device having a different subset of the instructions, an implementation consistent with usage of the singular term “medium” herein. In some cases, third party content delivery networks may host some or all of the information conveyed over networks, in which case, to the extent information (e.g., content) is said to be supplied or otherwise provided, the information may provided by sending instructions to retrieve that information from a content delivery network.

The reader should appreciate that the present application describes several independently useful techniques. Rather than separating those techniques into multiple isolated patent applications, applicants have grouped these techniques into a single document because their related subject matter lends itself to economies in the application process. But the distinct advantages and aspects of such techniques should not be conflated. In some cases, embodiments address all of the deficiencies noted herein, but it should be understood that the techniques are independently useful, and some embodiments address only a subset of such problems or offer other, unmentioned benefits that will be apparent to those of skill in the art reviewing the present disclosure. Due to costs constraints, some techniques disclosed herein may not be presently claimed and may be claimed in later filings, such as continuation applications or by amending the present claims. Similarly, due to space constraints, neither the Abstract nor the Summary of the Invention sections of the present document should be taken as containing a comprehensive listing of all such techniques or all aspects of such techniques.

It should be understood that the description and the drawings are not intended to limit the present techniques to the particular form disclosed, but to the contrary, the intention is to cover all modifications, equivalents, and alternatives falling within the spirit and scope of the present techniques as defined by the appended claims. Further modifications and alternative embodiments of various aspects of the techniques will be apparent to those skilled in the art in view of this description. Accordingly, this description and the drawings are to be construed as illustrative only and are for the purpose of teaching those skilled in the art the general manner of carrying out the present techniques. It is to be understood that the forms of the present techniques shown and described herein are to be taken as examples of embodiments. Elements and materials may be substituted for those illustrated and described herein, parts and processes may be reversed or omitted, and certain features of the present techniques may be utilized independently, all as would be apparent to one skilled in the art after having the benefit of this description of the present techniques. Changes may be made in the elements described herein without departing from the spirit and scope of the present techniques as described in the following claims. Headings used herein are for organizational purposes only and are not meant to be used to limit the scope of the description.

As used throughout this application, the word “may” is used in a permissive sense (i.e., meaning having the potential to), rather than the mandatory sense (i.e., meaning must). The words “include”, “including”, and “includes” and the like mean including, but not limited to. As used throughout this application, the singular forms “a,” “an,” and “the” include plural referents unless the content explicitly indicates otherwise. Thus, for example, reference to “an element” or “a element” includes a combination of two or more elements, notwithstanding use of other terms and phrases for one or more elements, such as “one or more.” The term “or” is, unless indicated otherwise, non-exclusive, i.e., encompassing both “and” and “or.” Terms describing conditional relationships, e.g., “in response to X, Y,” “upon X, Y,”, “if X, Y,” “when X, Y,” and the like, encompass causal relationships in which the antecedent is a necessary causal condition, the antecedent is a sufficient causal condition, or the antecedent is a contributory causal condition of the consequent, e.g., “state X occurs upon condition Y obtaining” is generic to “X occurs solely upon Y” and “X occurs upon Y and Z.” Such conditional relationships are not limited to consequences that instantly follow the antecedent obtaining, as some consequences may be delayed, and in conditional statements, antecedents are connected to their consequents, e.g., the antecedent is relevant to the likelihood of the consequent occurring. Statements in which a plurality of attributes or functions are mapped to a plurality of objects (e.g., one or more processors performing steps A, B, C, and D) encompasses both all such attributes or functions being mapped to all such objects and subsets of the attributes or functions being mapped to subsets of the attributes or functions (e.g., both all processors each performing steps A-D, and a case in which processor 1 performs step A, processor 2 performs step B and part of step C, and processor 3 performs part of step C and step D), unless otherwise indicated. Similarly, reference to “a computer system” performing step A and “the computer system” performing step B can include the same computing device within the computer system performing both steps or different computing devices within the computer system performing steps A and B. Further, unless otherwise indicated, statements that one value or action is “based on” another condition or value encompass both instances in which the condition or value is the sole factor and instances in which the condition or value is one factor among a plurality of factors. Unless otherwise indicated, statements that “each” instance of some collection have some property should not be read to exclude cases where some otherwise identical or similar members of a larger collection do not have the property, i.e., each does not necessarily mean each and every. Limitations as to sequence of recited steps should not be read into the claims unless explicitly specified, e.g., with explicit language like “after performing X, performing Y,” in contrast to statements that might be improperly argued to imply sequence limitations, like “performing X on items, performing Y on the X'ed items,” used for purposes of making claims more readable rather than specifying sequence. Statements referring to “at least Z of A, B, and C,” and the like (e.g., “at least Z of A, B, or C”), refer to at least Z of the listed categories (A, B, and C) and do not require at least Z units in each category. Unless specifically stated otherwise, as apparent from the discussion, it is appreciated that throughout this specification discussions utilizing terms such as “processing,” “computing,” “calculating,” “determining” or the like refer to actions or processes of a specific apparatus, such as a special purpose computer or a similar special purpose electronic processing/computing device. Features described with reference to geometric constructs, like “parallel,” “perpendicular/orthogonal,” “square”, “cylindrical,” and the like, should be construed as encompassing items that substantially embody the properties of the geometric construct, e.g., reference to “parallel” surfaces encompasses substantially parallel surfaces. The permitted range of deviation from Platonic ideals of these geometric constructs is to be determined with reference to ranges in the specification, and where such ranges are not stated, with reference to industry norms in the field of use, and where such ranges are not defined, with reference to industry norms in the field of manufacturing of the designated feature, and where such ranges are not defined, features substantially embodying a geometric construct should be construed to include those features within 15% of the defining attributes of that geometric construct. The terms “first”, “second”, “third,” “given” and so on, if used in the claims, are used to distinguish or otherwise identify, and not to show a sequential or numerical limitation. As is the case in ordinary usage in the field, data structures and formats described with reference to uses salient to a human need not be presented in a human-intelligible format to constitute the described data structure or format, e.g., text need not be rendered or even encoded in Unicode or ASCII to constitute text; images, maps, and data-visualizations need not be displayed or decoded to constitute images, maps, and data-visualizations, respectively; speech, music, and other audio need not be emitted through a speaker or decoded to constitute speech, music, or other audio, respectively. Computer implemented instructions, commands, and the like are not limited to executable code and can be implemented in the form of data that causes functionality to be invoked, e.g., in the form of arguments of a function or API call. To the extent bespoke noun phrases (and other coined terms) are used in the claims and lack a self-evident construction, the definition of such phrases may be recited in the claim itself, in which case, the use of such bespoke noun phrases should not be taken as invitation to impart additional limitations by looking to the specification or extrinsic evidence.

In this patent, to the extent any U.S. patents, U.S. patent applications, or other materials (e.g., articles) have been incorporated by reference, the text of such materials is only incorporated by reference to the extent that no conflict exists between such material and the statements and drawings set forth herein. In the event of such conflict, the text of the present document governs, and terms in this document should not be given a narrower reading in virtue of the way in which those terms are used in other materials incorporated by reference.

The present techniques will be better understood with reference to the following enumerated embodiments:
1. A multi-layer waveguide structure, comprising: a substrate comprising a wafer-scale or panel-scale interposer; a plurality of stacked optical waveguide layers disposed within or on the substrate, each waveguide layer configured to route optical signals along a predefined optical pathway; an electrical routing layer disposed adjacent to the plurality of stacked optical waveguide layers; a plurality of optical-electrical chiplets hybrid bonded to the substrate, each optical-electrical chiplet comprising: an emitter selected from the group consisting of a micro-light emitting diode, a vertical-cavity surface-emitting laser, or a quantum dot light emitting diode; and an optical detector; a plurality of optical couplers configured to optically couple the optical emitters and detectors to the stacked optical waveguide layers; and a bonding surface configured to electrically or optically connect one or more compute or memory dies to the interconnect structure.
2. The multi-layer waveguide structure of embodiment 1, wherein: the plurality of stacked optical waveguide layers comprises at least four optical waveguide layers, and inter-layer optical transitions are provided by vertical coupling structures selected from tapered vertical transitions, evanescent couplers, subwavelength-grating vertical couplers, or reflective turning elements formed within the interposer.
3. The multi-layer waveguide structure of embodiment 1, wherein: waveguide cores comprise at least one of silicon nitride (SiN), silicon oxynitride (SiON), aluminum oxide (Al₂O₃), polymer dielectric, or glass, and the waveguide cores comprise a cladding stack that comprises at least one of thermal silicon dioxide, low-pressure chemical-vapor-deposited silicon dioxide, or atomic-layer-deposited aluminum oxide.
4. The multi-layer waveguide structure of embodiment 1, wherein: the electrical routing layer comprises a polyimide-copper redistribution layer (PI-Cu RDL) and/or a silicon bridge, and the optical-electrical chiplets are Cu-Cu hybrid-bonded to recessed copper pads in CMP-planarized oxide of the electrical routing layer, with fine-pitch vertical vias extending from the chiplets to the electrical routing layer and keep-out regions proximate to optical cores.
5. The multi-layer waveguide structure of embodiment 1, wherein the stacked optical waveguide layers implement a hierarchical folded-Clos topology comprising: a first subset of the layers forming leaf-tier waveguides optically coupled to respective optical-electrical chiplets; a second, plane-disjoint subset of the layers forming spine-tier trunk waveguides; and inter-tier connections between the leaf-tier and spine-tier provided by vertical coupling structures selected from tapered vertical couplers, evanescent couplers, and grating-based vertical transitions; wherein the topology is configured so that any selected pair of endpoints associated with compute or memory dies is connectable by a path comprising a leaf-tier segment, at least one inter-tier vertical transition, a spine-tier trunk segment, and a return inter-tier transition to a receive port.
6. The multi-layer waveguide structure of embodiment 1, wherein the plurality of stacked optical waveguide layers and the optical-electrical chiplets are configured to provide optical bandwidth density of approximately 10 terabits per second per millimeter with energy per bit of approximately 1 picojoule per bit or less for intra-substrate links over wafer-scale or panel-scale distances supported by the waveguide stack.
7. The multi-layer waveguide structure of embodiment 1, further comprising interface circuitry configured to apply an integer multiplexing ratio M≥2 at an optical-electrical boundary.
8. A multi-layer waveguide structure, comprising: a substrate comprising a wafer-scale or panel-scale interposer; a plurality of stacked optical waveguide layers disposed within or on the substrate, each waveguide layer configured to route optical signals along a predefined optical pathway; an electrical routing layer disposed adjacent to the plurality of stacked optical waveguide layers; a plurality of optical-electrical chiplets hybrid bonded to the substrate, each optical-electrical chiplet comprising an optical detector; a plurality of optical couplers configured to receive optical signals from one or more external emitters and direct the received optical signals into the stacked optical waveguide layers; an external optical interface configured to couple the one or more external emitters to the optical couplers; and a bonding surface configured to electrically or optically connect one or more compute or memory dies to the interconnect structure.
9. The multi-layer waveguide structure of embodiment 8, wherein the plurality of stacked optical waveguide layers comprises at least two optical planes separated by dielectric cladding, each plane having waveguide cores formed from silicon nitride, silicon oxynitride, aluminum oxide, polymer dielectric, or glass, and cladding formed from thermal silicon dioxide, low-pressure chemical-vapor-deposited silicon dioxide, or atomic-layer-deposited aluminum oxide.
10. The multi-layer waveguide structure of embodiment 8, wherein the one or more external emitters comprise at least one of a laser diode, a vertical-cavity surface-emitting laser, a quantum-dot light-emitting device, or a remote laser optically coupled to a silicon-photonic modulator.
11. The multi-layer waveguide structure of embodiment 8, wherein each optical-electrical chiplet is hybrid-bonded to recessed copper pads within chemical-mechanical-polished oxide of the interposer and comprises an optical detector including a photodiode operably coupled to a transimpedance amplifier.
12. The multi-layer waveguide structure of embodiment 8, wherein: the plurality of optical couplers comprises subwavelength grating input ports, tapered vertical couplers, or evanescent coupling regions aligned to the external optical interface, and the external optical interface comprises plug-in fiber connectors registered to ferrule pockets and alignment fiducials at a top surface, an edge port, or an angled facet of the interposer.
13. A method of fabricating a multi-layer waveguide interposer structure, the method comprising: bonding a wafer comprising an electrical redistribution layer to a wafer comprising a first photonic layer, the first photonic layer comprising an array of optical emitter structures or photodetector structures configured for optical coupling via grating couplers, tapered transitions, or evanescent couplers; removing at least a portion of a handle substrate of the first photonic layer to expose the first photonic layer for subsequent integration; forming conductive vias through the first photonic layer to electrically connect the first photonic layer to the redistribution layer, the vias having a pitch of 10 μm or less; bonding a second photonic layer comprising an array of optical emitter structures or photodetector structures, and removing at least a portion of a handle substrate of the second photonic layer to expose the second photonic layer; bonding a waveguide-electrical interposer comprising four or more stacked optical waveguide layers configured to provide independent optical routing pathways; forming external connection features comprising hybrid bonding pads or solderable micro-bumps configured for electrical and optical input or output; and attaching at least one compute die, memory die, or power regulation component to the bonding surface of the interposer such that the die overlies at least a portion of the photonic or waveguide layers.
14. The method of embodiment 13, wherein bonding the wafer comprising the electrical redistribution layer to the first photonic layer further comprises hybrid bonding including oxide-to-oxide bonding with recessed metal pads and metal-to-metal bonding with copper-to-copper interfaces, the wafers being planarized by chemical-mechanical polishing and aligned by infrared alignment to embedded fiducials, followed by a room-temperature pre-bond and a low-or moderate-temperature anneal to complete the bond.
15. The method of embodiment 13, wherein removing at least a portion of the handle substrate further comprises: thinning, grinding, and chemical-mechanical polishing to a stop layer; and selective wet or dry etching to expose the photonic layer, the bonded stack being temporarily mounted to a carrier using a removable adhesive.
16. The method of embodiment 13, wherein forming external connection features comprises: fabricating under-bump metallization selected from Ni/Au or Ni/Pd/Au, forming copper pillars, micro-bumps, or ball-grid-array contacts for electrical I/O; and defining optical egress interfaces comprising surface-grating ports, edge couplers, or angled ports registered to ferrule pockets and alignment fiducials.
17. The method of embodiment 13, wherein forming conductive vias through the first photonic layer further comprises: patterning via openings by reactive-ion etching or deep reactive-ion etching, depositing insulating liners selected from silicon dioxide or silicon nitride; depositing barrier and seed layers selected from titanium, tantalum nitride, and copper; electroplating copper to fill the vias; and planarizing with metal-free keep-out regions maintained proximate to optical cores.
18. The method of embodiment 13, wherein bonding the waveguide-electrical interposer further comprises aligning interposer optical coupling features to apertures of the emitter or photodetector arrays, the coupling features comprising subwavelength grating couplers, tapered vertical couplers, evanescent coupling regions, or reflective turning elements.
19. The method of embodiment 13, further comprising steps for forming conductive vias.
20. The method of embodiment 13, wherein attaching at least one compute die comprises mounting a processor or AI-accelerator die and a high-bandwidth memory stack onto the bonding surface such that the processor die overlies the photonic or waveguide layers and is coupled to the stacked waveguide layers through optical-electrical chiplets and integrated couplers.
21. A tangible, non-transitory, machine-readable medium storing instructions that when executed by a data processing apparatus cause the data processing apparatus to perform operations comprising: the operations of any one of embodiments 13-20.
22. A system, comprising: one or more processors; and memory storing instructions that when executed by the processors cause the processors to effectuate operations comprising: the operations of any one of embodiments 13-20.

What is claimed is:

1. A multi-layer waveguide structure, comprising:
a substrate comprising a wafer-scale or panel-scale interposer;
a plurality of stacked optical waveguide layers disposed within or on the substrate, each waveguide layer configured to route optical signals along a predefined optical pathway;
an electrical routing layer disposed adjacent to the plurality of stacked optical waveguide layers;
a plurality of optical-electrical chiplets hybrid bonded to the substrate, each optical-electrical chiplet comprising:
an emitter selected from the group consisting of a micro-light emitting diode, a vertical-cavity surface-emitting laser, or a quantum dot light emitting diode; and
an optical detector;
a plurality of optical couplers configured to optically couple the optical emitters and detectors to the stacked optical waveguide layers; and
a bonding surface configured to electrically or optically connect one or more compute or memory dies to the structure.

2. The multi-layer waveguide structure of claim 1, wherein:
the plurality of stacked optical waveguide layers comprises at least two optical waveguide layers, and
inter-layer optical transitions are provided by vertical coupling structures selected from tapered vertical transitions, evanescent couplers, subwavelength-grating vertical couplers, or reflective turning elements formed within the interposer.

3. The multi-layer waveguide structure of claim 1, wherein:
waveguide cores comprise at least one of silicon nitride, silicon oxynitride, aluminum oxide, polymer dielectric, or glass, and
the waveguide cores comprise a cladding stack that comprises at least one of thermal silicon dioxide, low-pressure chemical-vapor-deposited silicon dioxide, atomic-layer-deposited aluminum oxide, physical vapor deposited aluminum oxide, or aluminum oxide grown via anodization.

4. The multi-layer waveguide structure of claim 1, wherein:
the electrical routing layer comprises a polyimide-copper redistribution layer and/or a silicon bridge, and
the optical-electrical chiplets are Cu-Cu hybrid-bonded to recessed copper pads in CMP-planarized oxide of the electrical routing layer, with fine-pitch vertical vias extending from the chiplets to the electrical routing layer and keep-out regions proximate to optical cores.

5. The multi-layer waveguide structure of claim 1, wherein the stacked optical waveguide layers implement a hierarchical folded-Clos topology comprising:
a first subset of the layers forming leaf-tier waveguides optically coupled to respective optical-electrical chiplets;
a second, plane-disjoint subset of the layers forming spine-tier trunk waveguides; and
inter-tier connections between the leaf-tier and spine-tier provided by vertical coupling structures selected from tapered vertical couplers, evanescent couplers, and grating-based vertical transitions;
wherein the topology is configured so that any selected pair of endpoints associated with compute or memory dies is connectable by a path comprising a leaf-tier segment, at least one inter-tier vertical transition, a spine-tier trunk segment, and a return inter-tier transition to a receive port.

6. The multi-layer waveguide structure of claim 1, wherein the plurality of stacked optical waveguide layers and the optical-electrical chiplets are configured to provide optical bandwidth density of approximately 10 terabits per second per millimeter with energy per bit of approximately 1 picojoule per bit or less for intra-substrate links over wafer-scale or panel-scale distances supported by the waveguide stack.

7. The multi-layer waveguide structure of claim 1, wherein the substrate further comprises a light-blocking coating disposed adjacent to at least one of a vertical coupling waveguide, a horizontal waveguide of the plurality of stacked optical waveguide layers, a dielectric lens or coupling layer of an optical interface stack, or an optoelectronic pixel region of at least one of the optical-electrical chiplets, the light-blocking coating comprising at least one metal layer.

8. A multi-layer waveguide structure, comprising:
a substrate comprising a wafer-scale or panel-scale interposer;
a plurality of stacked optical waveguide layers disposed within or on the substrate, each waveguide layer configured to route optical signals along a predefined optical pathway;
an electrical routing layer disposed adjacent to the plurality of stacked optical waveguide layers;
a plurality of optical-electrical chiplets hybrid bonded to the substrate, each optical-electrical chiplet comprising an optical detector;
a plurality of optical couplers configured to receive optical signals from one or more external emitters and direct the received optical signals into the stacked optical waveguide layers;
an external optical interface configured to couple the one or more external emitters to the optical couplers; and
a bonding surface configured to electrically or optically connect one or more compute or memory dies to the waveguide structure.

9. The multi-layer waveguide structure of claim 8, wherein the plurality of stacked optical waveguide layers comprises at least four optical planes separated by dielectric cladding, each plane having waveguide cores formed from silicon nitride, silicon oxynitride, aluminum oxide, polymer dielectric, or glass, and cladding formed from thermal silicon dioxide, low-pressure chemical-vapor-deposited silicon dioxide, atomic-layer-deposited aluminum oxide, or aluminum oxide deposited by physical vapor deposition or anodization.

10. The multi-layer waveguide structure of claim 8, wherein at least one of the plurality of optical couplers comprises a coupling waveguide having an entrance opening with a size and shape selected based on one or more characteristics of a corresponding external emitter.

11. The multi-layer waveguide structure of claim 8, wherein at least one of the optical couplers comprises:
a vertical waveguide capture structure configured to receive optical energy from the one or more external emitters in a predominantly vertical propagation direction; and
a lateral light deviator optically coupled between the vertical waveguide capture structure and a horizontal waveguide of the plurality of stacked optical waveguide layers, the lateral light deviator configured to redirect at least a portion of the optical energy into a predominantly horizontal propagation direction for coupling into the horizontal waveguide.

12. The multi-layer waveguide structure of claim 8, wherein:
the plurality of optical couplers comprises subwavelength grating input ports, tapered vertical couplers, or evanescent coupling regions aligned to the external optical interface, and
the external optical interface comprises plug-in fiber connectors registered to ferrule pockets and alignment fiducials at a top surface, an edge port, or an angled facet of the interposer.

13. A method of fabricating a multi-layer waveguide interposer structure, the method comprising:
bonding a wafer comprising an electrical redistribution layer to a wafer comprising a first photonic layer, the first photonic layer comprising an array of optical emitter structures or photodetector structures configured for optical coupling via grating couplers, tapered transitions, or evanescent couplers;
removing at least a portion of a handle substrate of the first photonic layer to expose the first photonic layer for subsequent integration;
forming conductive vias through the first photonic layer to electrically connect the first photonic layer to the redistribution layer, the vias having a pitch of 10μm or less;
bonding a second photonic layer comprising an array of optical emitter structures or photodetector structures, and removing at least a portion of a handle substrate of the second photonic layer to expose the second photonic layer;
bonding a waveguide-electrical interposer comprising four or more stacked optical waveguide layers configured to provide independent optical routing pathways;
forming external connection features comprising hybrid bonding pads or solderable micro-bumps configured for electrical and optical input or output; and
attaching at least one compute die, memory die, or power regulation component to a bonding surface of the interposer such that the die overlies at least a portion of the photonic or waveguide layers.

14. The method of claim 13, wherein bonding the wafer comprising the electrical redistribution layer to the first photonic layer further comprises hybrid bonding including oxide-to-oxide bonding with recessed metal pads and metal-to-metal bonding with copper-to-copper interfaces, the wafers being planarized by chemical-mechanical polishing and aligned by infrared alignment to embedded fiducials, followed by a room-temperature pre-bond and a low-or moderate-temperature anneal to complete the bond.

15. The method of claim 13, wherein bonding the wafer comprising the electrical redistribution layer to the wafer comprising the first photonic layer further comprises:
hybrid bonding the first photonic layer to an electrical substrate implemented as copper routing layers and organic dielectric build-up layers formed on a substrate core, the build-up layers comprising at least one of Ajinomoto build-up film and polyimide,
wherein the hybrid bonding includes forming inorganic hybrid-bond-capable layers comprising silicon oxide or silicon nitride on mating surfaces of the electrical substrate and the first photonic layer at a temperature less than or equal to approximately 400°C.

16. The method of claim 13, wherein forming external connection features comprises:
forming under-bump metallization comprising a nickel-gold stack or a nickel-palladium-gold stack;
forming copper pillars, micro-bumps, or ball-grid-array contacts for electrical I/O; and
defining optical egress interfaces comprising surface-grating ports, edge couplers, or angled ports registered to ferrule pockets and alignment fiducials.

17. The method of claim 13, wherein forming conductive vias through the first photonic layer further comprises:
patterning via openings by reactive-ion etching or deep reactive-ion etching, depositing insulating liners selected from silicon dioxide or silicon nitride;
depositing barrier and seed layers selected from titanium, tantalum nitride, and copper;
electroplating copper to fill the vias; and
planarizing with metal-free keep-out regions maintained proximate to optical cores.

18. The method of claim 13, wherein bonding the waveguide-electrical interposer further comprises aligning interposer optical coupling features to apertures of the emitter or photodetector arrays, the coupling features comprising subwavelength grating couplers, tapered vertical couplers, evanescent coupling regions, or reflective turning elements.

19. The method of claim 13, further comprising steps for forming conductive vias.

20. The method of claim 13, wherein attaching at least one compute die comprises mounting a processor or AI-accelerator die and a high-bandwidth memory stack onto the bonding surface such that the processor die overlies the photonic or waveguide layers and is coupled to the stacked waveguide layers through optical-electrical chiplets and integrated couplers.
